(19) United States
(12) Patent Application Publication
(10) Pub. No.: US 2026/0239805 A1
(43) Pub. Date: Aug. 13, 2026

(54) BILAYER ELECTRODES FOR PEROVSKITE SOLAR CELLS

(71) Applicants: Alliance for Sustainable Energy, LLC, Golden, CO (US); Board of Trustees of Northern Illinois University, DeKalb, IL (US)

(72) Inventors: Kai ZHU, Littleton, CO (US); Soyeon PARK, Lakewood, CO (US); Tao XU, Naperville, IL (US)

(21) Appl. No.: 19/470,953

(22) PCT Filed: Apr. 8, 2024
(86) PCT No.: PCT/US2024/023593

§ 371 Date: Sep. 30, 2025

Related U.S. Application Data
(60) Provisional application No. 63/494,873, filed on Apr. 7, 2023.

(51) Int. Cl. H10K 30/40; H10K 30/84; H10K 85/20; H10K 85/50

(52) U.S. Cl. CPC H10K 30/40; H10K 30/84; H10K 85/20; H10K 85/50

(57) ABSTRACT

The present disclosure relates to a device that includes a first electrode layer constructed of a material having a melting point less than or equal to 200° C., a first charge transport layer (CTL), and an active layer, where the CTL is positioned between the first electrode layer and the active layer. In some embodiments of the present disclosure, the melting point may be between 100° C. and 200° C.

### CROSS-REFERENCE TO RELATED APPLICATIONS

This application claims priority from U.S. Provisional Patent Application No. 63/494,873 filed on Apr. 7, 2023, the contents of which are incorporated herein by reference in the entirety.

### CONTRACTUAL ORIGIN

This invention was made with government support under Contract No. DE-AC36-08GO28308 awarded by the Department of Energy and Contract No. DMR-1806152 awarded by the National Science Foundation. The government has certain rights in the invention.

### BACKGROUND

With the rapid development of perovskite solar cells (PSCs), lowering fabrication costs for PSCs has become a prominent challenge for commercialization. At present, gold is commonly used as the back metal electrode in state-of-the-art n-i-p structured PSCs due to its compatible work function and excellent conductivity. However, the high cost of gold and the dependence on vacuum-based thin-film coating facilities may impede large-scale manufacture of PSCs. Thus, there remains a need for lower cost electrodes and methods for depositing them onto large surface area PSCs.

### SUMMARY

An aspect of the present disclosure is a device that includes a first electrode layer constructed of a material having a melting point less than or equal to 200° C., a first charge transport layer (CTL), and an active layer, where the CTL is positioned between the first electrode layer and the active layer. In some embodiments of the present disclosure, the melting point may be between 100° C. and 200° C.

In some embodiments of the present disclosure, the material may include a metal. In some embodiments of the present disclosure, the metal may include at least one of bismuth, lead, tin, cadmium, zinc, indium, gallium, antimony, and/or thallium. In some embodiments of the present disclosure, the metal may include bismuth and indium. In some embodiments of the present disclosure, bismuth may be present in the first electrode layer at a concentration between 5 wt % and 95 wt %. In some embodiments of the present disclosure, the first electrode layer may have a thickness between 0.1 μm and 50 μm.

In some embodiments of the present disclosure, a device may further include a second electrode layer, wherein the second electrode layer is positioned between the first electrode layer and the CTL. In some embodiments of the present disclosure, the second electrode layer may include carbon. In some embodiments of the present disclosure, the second electrode layer may include at least one of graphite, carbon-black, and/or a carbon nanotube. In some embodiments of the present disclosure, the second electrode layer may include graphite.

In some embodiments of the present disclosure, the second electrode layer may further include a metal. In some embodiments of the present disclosure, the metal of the second electrode layer may include a transition metal. In some embodiments of the present disclosure, the metal of the second electrode layer may include at least one of nickel, cobalt, and/or tungsten. In some embodiments of the present disclosure, the metal of the second electrode layer may be present at a concentration between greater than 0 wt % and less than or equal to 30 wt %. In some embodiments of the present disclosure, the metal of the second electrode layer may be in a particulate form having an average particle size between 10 nm and 10 μm. In some embodiments of the present disclosure, the second electrode layer may have a thickness between 0.1 μm and 50 μm.

In some embodiments of the present disclosure, the absorber layer may include a perovskite. In some embodiments of the present disclosure, the perovskite may include a first cation (A), a second cation (B), and an anion (X).

An aspect of the present disclosure is a method that includes synthesizing metal particles, synthesizing a mixture that includes the metal particles and a carbon-containing material, applying the mixture to a device stack that includes a perovskite layer, resulting in the forming of a layer that includes the carbon-containing material and the metal particles, and applying a fusible metal or alloy in liquid form to a surface of the layer that includes the carbon-containing material and the metal particles, resulting in the forming of a solid layer of the fusible metal or alloy.

### BRIEF DESCRIPTION OF DRAWINGS

Some embodiments are illustrated in referenced figures of the drawings. It is intended that the embodiments and figures disclosed herein are to be considered illustrative rather than limiting.

FIGS. 1A and 1B illustrate a perovskite in a corner-sharing, cubic phase arrangement, according to some embodiments of the present disclosure.

FIG. 2A illustrates three possible corner-sharing phases for perovskites, Panel A, cubic phase (i.e., α-ABX₃), Panel B, a tetragonal crystalline phase (i.e., β-ABX₃), and Panel C, an orthorhombic crystalline phase (i.e., γ-ABX₃), according to some embodiments of the present disclosure.

FIG. 2B illustrates a perovskite in one of three possible phases, the cubic phase (i.e., α-phase), compared to two non-perovskite phases (i.e., non-corner sharing), according to some embodiments of the present disclosure.

FIG. 3 illustrates 2D, 1D, and 0D perovskite-like structures, in Panels A, B, and C, respectively, according to some embodiments of the present disclosure.

FIG. 4 illustrates a device, according to some embodiments of the present disclosure.

FIG. 5 illustrates a method for making a device like that illustrated in FIG. 1, according to some embodiments of the present disclosure.

FIG. 6 illustrates (Panel A) a schematic of a method for synthesizing nickel particles, (Panel B) a schematic of a method for synthesizing nickel-doped graphite (i.e., a metal-doped carbon material), and (Panel C) photos of bulky nickel particles, natural graphite powder, and nickel-doped graphite powder (i.e., a metal-doped carbon material), according to some embodiments of the present disclosure.

FIG. 7 illustrates photographs of dispersions of graphite, nickel, and nickel-doped graphite in ethanol, according to some embodiments of the present disclosure.

FIG. 8 illustrates (Panel A) a schematic for fabricating a bilayer electrode on a PSC device and (Panel B) a top view of photos of an exemplary charge transport layer (spiro-OMeTAD), an exemplary metal-doped carbon layer (Ni-doped graphite), and an exemplary alloy layer (Bi—In alloy), according to some embodiments of the present disclosure.

FIG. 9 illustrates (Panel A) an exemplary uncoated charge transport layer (spiro-OMeTAD), (Panel B) Kapton tape applied to the charge transport layer to divide the whole area into two independent parts, (Panel C) a scale ruler used as reference to calculate the active area, (Panel D) the Spiro-OMeTAD charge transport layer coated with a metal-doped carbon layer of Ni-doped graphite, (Panel E) the metal-doped carbon layer coated with an alloy layer of Bi—In alloy, and (Panel F) a customized shadow mask applied to the glass side of the device, according to some embodiments of the present disclosure.

FIGS. 10A-C illustrate J-V curves of perovskite solar cell devices based on an alloy (FIG. 10A), undoped graphite (FIG. 10B), and Au (FIG. 10C) electrodes, according to some embodiments of the present disclosure.

FIG. 11A illustrates a J-V curve of a PSC device based on a bilayer electrode constructed using an undoped carbon layer of graphite and an alloy layer (G/alloy), according to some embodiments of the present disclosure.

FIG. 11B illustrates a J-V curve of a PSC device based on a bilayer electrode constructed using a metal-doped carbon layer of 10 wt % nickel with graphite and an alloy layer (10Ni-G/alloy), according to some embodiments of the present disclosure.

FIG. 11C illustrates the square resistivities of Bi—In alloy, undoped graphite, 10Ni-G, 20Ni-G, and Ni, according to some embodiments of the present disclosure.

FIG. 11D illustrates UPS spectra of a Bi—In alloy, undoped graphite, 10Ni-G, 20Ni-G, and Ni, according to some embodiments of the present disclosure.

FIG. 11E illustrates an energy diagram of spiro-OMeTAD, Bi—In alloy, undoped graphite, 10Ni-G, 20Ni-G, and Ni, according to some embodiments of the present disclosure.

FIG. 12 illustrates photos showing the wettability of a Bi—In alloy layer on undoped graphite and on nickel, according to some embodiments of the present disclosure. The Bi—In alloy showed very good wettability (top image) on the pure graphite layer but poor wettability on the nickel layer (bottom image).

FIG. 13 illustrates XRD spectra of graphite, nickel, and nickel-doped graphite, according to some embodiments of the present disclosure. The absence of any diffraction patterns in the nickel particles clearly shows the amorphous nature of the nickel particles. The characteristic XRD peaks for graphite are clearly identified.

FIG. 14 illustrates SEM images with 100-μm, 10-μm, and 1-μm scale bars (from left to right) for natural graphite (top row), nickel particles (middle row), and nickel-doped graphite (bottom), according to some embodiments of the present disclosure.

FIG. 15 illustrates surface SEM images of nickel-doped graphite (Panel A) and undoped graphite (Panel B), surface EDX mapping of elemental nickel (Panel C), and elemental carbon (Panel D), for the surface of nickel-doped graphite, and elemental carbon (Panel E) for the surface of undoped graphite, according to some embodiments of the present disclosure.

FIG. 16A illustrates an XPS survey scan spectra of graphite, nickel, and nickel-doped graphite, according to some embodiments of the present disclosure.

FIG. 16B illustrates an XPS C1s scan spectra of graphite and nickel-doped graphite, according to some embodiments of the present disclosure.

FIG. 16C illustrates an XPS Ni2p scan spectra of nickel and nickel-doped graphite, according to some embodiments of the present disclosure. After removal of the surface nickel oxide layer (binding energy=855.7 eV for Ni2+) by Ar+ sputtering, the binding energy of the Ni metal particle is 852.2 eV.

FIG. 17A illustrates J-V curves of PSC devices based on a bilayer electrode (10Ni-G/alloy) and a gold electrode, according to some embodiments of the present disclosure.

FIG. 17B illustrates IPCE spectra and integrated current density of gold-based and 10Ni-G/alloy-based PSC devices, according to some embodiments of the present disclosure.

FIG. 17C illustrates J-V curves of a PSC device having a bilayer electrode (10Ni-G/alloy) PSC and a large active area (1 cm2), according to some embodiments of the present disclosure.

FIG. 17D illustrates a cross-section SEM image of a PSC having a bilayer electrode (10Ni-G/alloy), according to some embodiments of the present disclosure.

FIG. 17E illustrates long-term stability data of PSC devices, on having a gold electrode and another having a bilayer electrode (10Ni-G/alloy) under ambient storage conditions, according to some embodiments of the present disclosure.

### REFERENCE NUMERALS

| | |
|---|---|
| 100 | perovskite |
| 110 | A-cation |
| 120 | B-cation |
| 130 | X-anion |
| 400 | device |
| 410 | substrate |
| 420 | first electrode |
| 430 | first charge transport layer (CTL) |
| 440 | active layer |
| 450 | second CTL |
| 460 | second electrode |
| 463 | metal-doped or undoped carbon layer (i.e., first layer) |
| 466 | alloy layer (i.e., second layer) |
| 500 | method |
| 510 | synthesizing metal particles |
| 520 | synthesizing carbon-metal mixture |
| 530 | applying carbon-metal mixture |
| 540 | applying alloy |

### DETAILED DESCRIPTION

The present disclosure relates to a bilayer electrode configuration that includes a first electrode layer constructed of a metal-doped carbon layer, e.g., Ni-doped graphite layer, and a second electrode layer constructed of a low melting temperature metal or alloy, e.g., a bismuth and indium alloy layer. As shown herein, in some examples a metal or alloy used to construct a second electrode layer of a bilayer electrode may have a melting point below 200° C. Among other things, the use of a relatively low-melting point metal or alloy enables a vacuum-free method to produce the bilayer electrode. As shown herein, such a bilayer design for an electrode was successfully incorporated into PSCs having power conversion efficiencies up to 21.0%. The inexpensive materials and facile fabrication techniques available to produce such bilayer electrodes provide an appealing low-cost solution for manufacturing PSCs.

Thus, described herein is a vacuum-free, low-cost, manufacturing method capable of synthesizing bilayer electrodes suitable in both n-i-p and p-i-n structured PSCs, without the use of mechanical pressurization, e.g., via a mechanical press. Eliminating mechanical pressurization simplifies the manufacturing process. As the name suggests, a bilayer electrode includes two layers positioned in physical contact with one another. In some embodiments of the present disclosure, a first electrode layer may be constructed using a metal-doped carbon layer, such as a nickel-doped natural graphite layer (unprocessed graphite after removal from the ground and abbreviated herein as Ni-G). The material selected to construct a first electrode layer may by guided by selecting a material having a proper work function (WF) for interfacial charge extraction with the second electrode layer. In some embodiments of the present disclosure, this may be achieved by pairing a second electrode layer constructed with a low melting point metal or alloy, for example a bismuth-indium (Bi—In) alloy, deposited into a first electrode constructed using a metal-doped carbon layer.

Due to the atomically flat 2D structure of graphite made of loose bonding graphene layers, a graphite layer, used in a first electrode layer, can be seamlessly overlaid onto a charge transport layer (CTL), either a hole transport layer (HTL) or an electron transport layer (ETL), by applying a gentle mechanical force such as rubbing, pressing, and/or rolling the graphite onto the surface of the CTL. In some embodiments of the present disclosure, a first electrode layer of a metal-doped carbon layer (e.g., nickel-doped graphite) or an undoped carbon layer (e.g., essentially pure or pure graphite) may be applied to an underlying charge transport layer (CTL) using a force between 0.01 Newton and 10 Newton, or between 0.01 Newton and 1 Newton.

Further, as shown herein, doping metal (e.g., nickel particles) into a carbon such as graphite, can result in the forming of a metal-doped carbon layer, a first electrode layer, that very effectively suppresses the ingress of the metal and/or alloy present in a second electrode layer into a first electrode layer. Among other things, prevention of the mass transfer of material from a first electrode layer into a second electrode layer may improve the WF of the carbon-containing first electrode layer, e.g., constructed using graphite, thereby aligning it with the Fermi level of the CTL, e.g., spiro-OMeTAD, poly(triaryl amine) (PTAA), and/or nickel oxide, when the CTL is an HTL.

In some embodiments of the present disclosure, a complete, conformal second electrode layer, e.g., a Bi—In alloy layer (with a melting temperature of about 110° C.) may be deposited in a liquid form onto a surface of another earlier deposited layer. In some embodiments of the present disclosure, a previously deposited layer may be a first electrode layer, for example a metal-doped carbon layer such as a nickel-doped graphite layer. Such a depositing of a layer constructed of a low melting temperature metal or alloy may be conveniently completed at ambient atmospheric conditions (e.g., one atmosphere of pressure and/or at room temperature). Use of such a low temperature melting alloy can reduce the relatively high serial resistance of the resultant bilayer electrode, resulting in higher V_{oc} and FF values of the devices using these bilayer electrode designs. As shown herein, a FAPbI₃-based PSC device with such a bilayer electrode achieved a PCE of 21.0%. Thus, the bilayer electrodes described herein enable a practical manufacturing method that utilizes low temperature and atmospheric conditions for making lower-cost PSCs.

The method of utilizing low melting temperature metals or alloys, and the corresponding advantages of being able to deposit them in ambient conditions is also applicable for depositing the back electrode for p-i-n type PSCs. For the typical p-i-n type (or inverted) perovskite solar cell, an exemplary device configuration is ITO/SAM/Perovskite/C₆₀/BCP (or SnO₂)/metal. Here, SAM stands for self-assembled monolayer and BCP stands for bathocuproine. In this example, the SAM is the HTL and the C₆₀/BCP and/or SnO₂ provides an ETL. Both BCP and SnO₂ layers are robust enough to withstand the deposition of a low melting temperature metal or alloy onto their surfaces. Other examples of materials suitable for use in the ETL of a p-i-n device include fullerene-based materials such as C₆₀, C₇₀, phenyl-C₆₁-butyric acid methyl ester (PCBM), and/or other derivatives (such as fulleropyrrolidinium iodide [C₆₀-bis], indene-C₆₀ bis-adduct [ICBA], and/or C₆₀-fused N-methylpyrrolidine-m-C₁₂-phenyl [CMC]). Other ETMs include n-type metal oxides such as tin oxide, zinc oxide, titanium oxide, and/or cerium oxide. ETMs can be used alone, combined and/or blended, such as in PCBM/C₆₀, CMC+ICBA, PCBM/CeOₓ, and/or C₆₀/SnO₂. The same metals or alloys described above for synthesizing a second electrode layer, e.g, bismuth and indium, may be selected for a p-i-n device as described for an n-i-p device. As with n-i-p device, the melting point (between 100° C. and 130° C.) and work function (between 4.2 eV and 4.5 eV) of a metal or alloy used in a second electrode layer to be included in a p-i-n device can be adjusted by varying the ratio of the metals included in an alloy.

Further, in some embodiments of the present disclosure, an electrode layer may not require the use of a bilayer design. In some embodiments, depending on the materials of construction of the CTL contacting the electrode, an electrode may only have a “second” electrode layer constructed using a low melting temperature metal or alloy. For example, when a CTL is constructed of a carbon-containing or carbonaceous material such as a fullerene-based material, the CTL itself may provide the benefits described above by a “first” electrode layer; e.g., a carbon layer and/or a metal-doped carbon layer, eliminating the need for including an additional carbon-containing layer, i.e., eliminating the need for a first electrode layer.

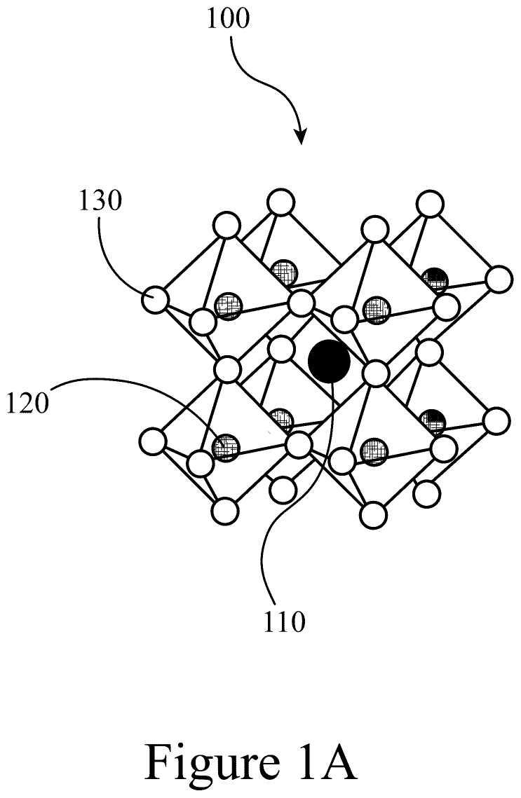

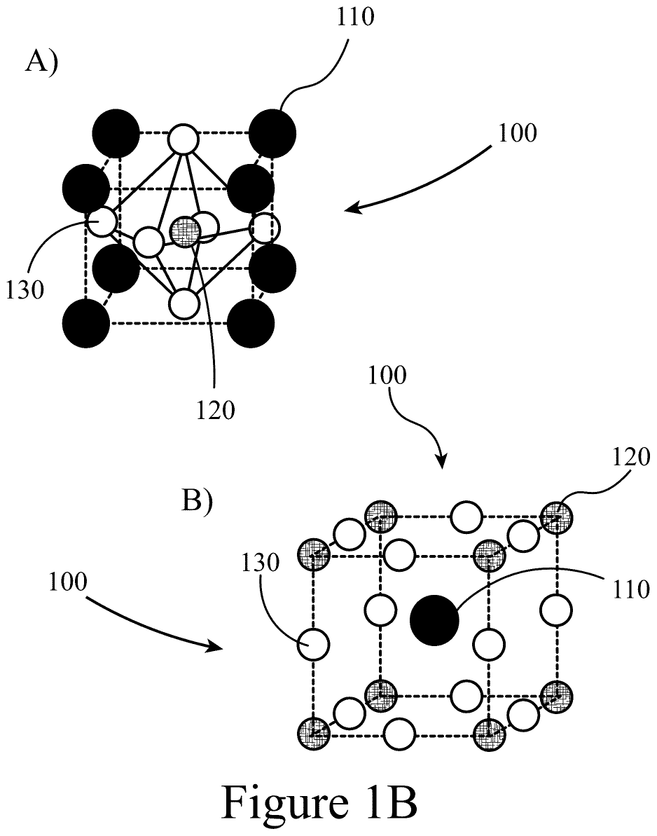

In general, the term “perovskite” refers to compositions having a network of corner-sharing BX₆ octahedra resulting in the general stoichiometry of ABX₃. FIGS. 1A and 1B illustrate that perovskites 100, for example metal halide perovskites, may organize into a three-dimensional (3D) cubic crystalline structures (i.e., α-phase or α-ABX₃) constructed of a plurality of corner-sharing BX₆ octahedra. In the general stoichiometry for a perovskite, ABX₃, X (130) is an anion and A (110) and B (120) are cations, typically of different sizes. FIG. 1A illustrates that a perovskite 100 having an α-phase structure may be further characterized by eight BX₆ octahedra surrounding a central A-cation 110, where each octahedra is formed by six X-anions 130 surrounding a central B-cation 120 and each of the octahedra are linked together by “corner-sharing” of anions, X (130).

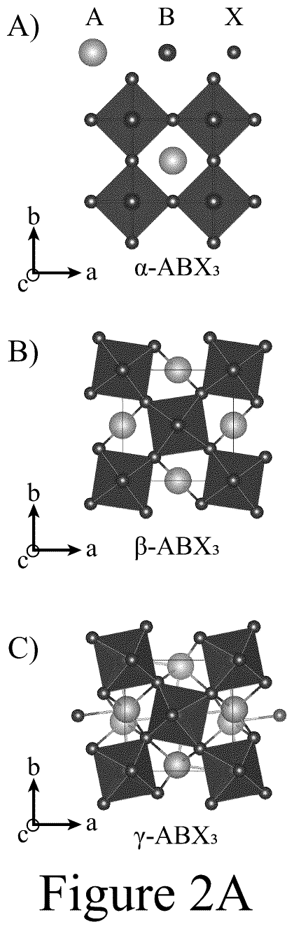

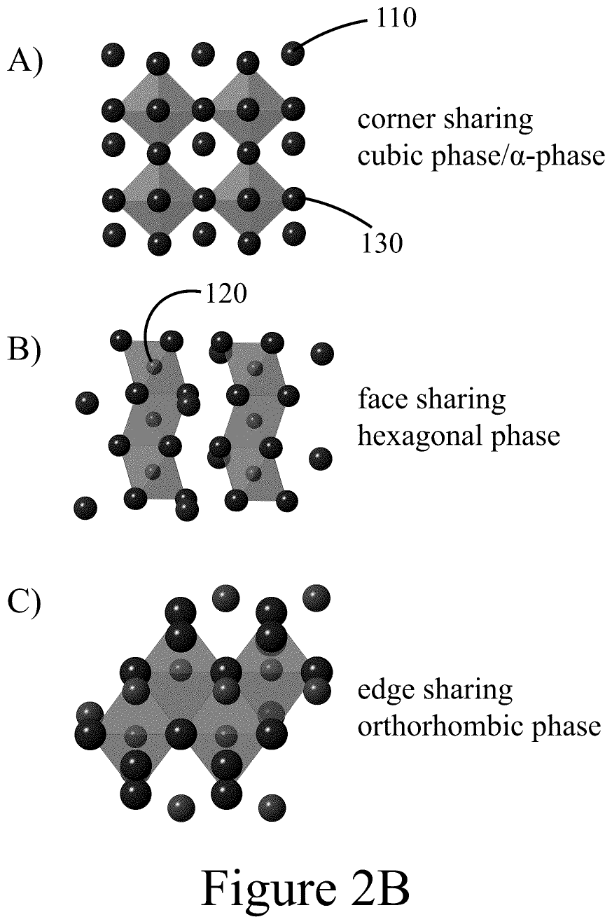

Panel A of FIG. 1B provides another visualization of a perovskite 100 in the α-phase, also referred to as the cubic phase. This is because, as illustrated in FIG. 1B, a perovskite in the α-phase may be visualized as a cubic unit cell, where the B-cation 120 is positioned at the center of the cube, an A-cation 110 is positioned at each corner of the cube, and an X-anion 130 is face-centered on each face of the cube. Panel B of FIG. 1B provides another visualization of the cubic unit cell of an α-phase perovskite, where the B-cation 120 resides at the eight corners of a cube, while the A-cation 110 is located at the center of the cube and with 12 X-anions 130 centrally located between B-cations 120 along each edge of the unit cell. For both unit cells illustrated in FIGS. 1B, the A-cations 110, the B-cations 120, and the X-anions 130 balance to the general formula ABX₃ of a perovskite, after accounting for the fractions of each atom shared with neighboring unit cells. For example, referring to Panel A of FIG. 1B, the single B-cation 120 atom is not shared with any of the neighboring unit cells. However, each of the six X-anions 130 is shared between two unit cells, and each of the eight A-cations 110 is shared between eight unit cells. So, for the unit cell illustrated in Panel A of FIG. 1B, the stoichiometry simplifies to B=1, A=8*0.125=1, and X=6*0.5=3, or ABX₃. Similarly, referring again to Panel B of FIG. 1B, since the A-cation is centrally positioned, it is not shared with any of the unit cells neighbors. However, each of the 12 X-anions 130 is shared between four neighboring unit cells, and each of the eight B-cations 120 is shared between eight neighboring unit cells, resulting in A=1, B=8*0.125=1, and X=12*0.25=3, or ABX₃. Referring again to Panel B of FIG. 1B, the X-anions 130 and the B-cations 120 of a perovskite in the α-phase are aligned along an axis; e.g., where the angle at the X-anion 130 between two neighboring B-cations 120 is exactly 180 degrees, referred to herein as the tilt angle. However, as illustrated in FIG. 2A, a perovskite 100 may assume other corner-sharing crystalline phases having tilt angles not equal to 180 degrees.

FIG. 2A illustrates that a perovskite can assume other crystalline forms while still maintaining the criteria of an ABX₃ stoichiometry with neighboring BX₆ octahedra maintaining X anion (130) corner-sharing. Thus, in addition to α-ABX₃ perovskites (in the cubic phase) having a tilt angle of 180 degrees, illustrated in Panel A of FIG. 2A, a perovskite may also assume a tetragonal crystalline phase (i.e., β-ABX₃) (see Panel B of FIG. 2A) and/or an orthorhombic crystalline phase (i.e., γ-ABX₃) (see Panel C of FIG. 2A), where the adjacent octahedra are tilted relative to the reference axes a, b, and c.

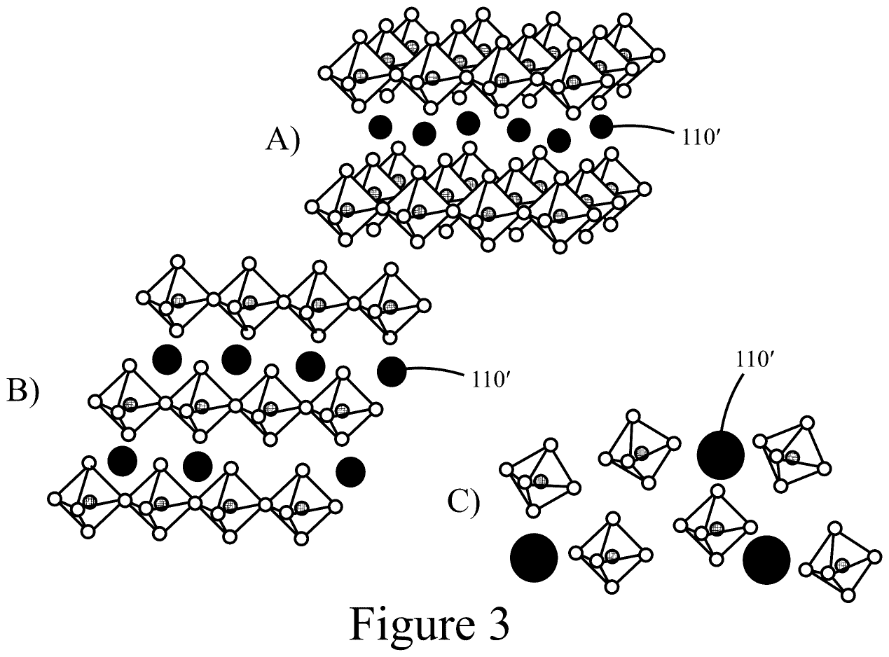

FIG. 2B illustrates that the elements used to construct a perovskite, as described above, A-cations 110, B-cations 120, and X-anions 130, may result in 3D non-perovskite structures; i.e., structures where neighboring BX₆ octahedra are not X-anion 130 corner-sharing and/or do not have a unit structure that simplifies to the ABX₃ stoichiometry. Panel B of FIG. 2B illustrates a perovskite in the cubic phase, i.e., α-ABX₃, compared to a non-perovskite structure constructed of face-sharing BX₆ octahedra resulting in a hexagonal crystalline structure (see Panel B of FIG. 2B) and a non-perovskite structure constructed of edge-sharing BX₆ octahedra resulting in an orthorhombic crystalline structure (see Panel C of FIG. 2B). Further, referring now to FIG. 3, the elements used to construct a perovskite, as described above, A-cations 110, B-cations 120, and X-anions 130, may result in non-3D (i.e., lower dimensional structures) perovskite-like structures such as two-dimensional (2D) structures, one-dimensional (1D) structures, and/or zero-dimensional (0D) structures. As illustrated in FIG. 3, such lower dimensional, perovskite-like structures still include the BX₆ octahedra, and depending on the dimensionality, e.g., 2D or 1D, may still maintain a degree of X-anion corner-sharing. However, as illustrated in FIG. 3, the X-anion 130 corner-sharing connectivity of neighboring octahedra of such lower dimensional structures, i.e., 2D, 1D, and 0D, is disrupted by intervening A-cations 110. Such a disruption of the neighboring octahedra, can be achieved by, among other things, varying the size of the intervening A-cations 110.

Referring to Panel A of FIG. 3, a 3D perovskite may be transformed to a 2D perovskite-like structure, 1D perovskite-like structure, and/or 0D perovskite-like structure. Where the degree of X-anion 130 corner sharing decreases and the stoichiometry changes according to the formula (A′)ₘ(A)ₙ₋₁BₙX₃ₙ₊₁, where monovalent (m=2) or divalent (m=1) A′ cations 110′ can intercalate between the X-anions of 2D perovskite-like sheets. Referring to Panel B of FIG. 3, 1D perovskite-like structures are constructed by BX₆ octahedral chained segments spatially isolated from each other by surrounding bulky organic A′-cations 110′, leading to bulk assemblies of paralleled octahedral chains. Referring to Panel C of FIG. 3, typically, the 0D perovskite-like structures are constructed of isolated inorganic octahedral clusters and surrounded by small A′-cations 110′, which may be connected via hydrogen bonding. In general, as n approaches infinity the structure is a pure 3D perovskite and when n is equal to 1, the structure is a pure 2D perovskite-like structure. More specifically, when n is greater than 10 the structure is considered to be essentially a 3D perovskite material and when n is between 1 and 5, inclusively, the structure is considered substantially a 2D perovskite-like material. For simplification, as used herein the term “perovskite” will refer to each of the structures illustrated in FIGS. 1A, 1B, 2A, 2B, and 3, unless specified otherwise.

In some embodiments of the present invention, the A-cation 110 may include a nitrogen-containing organic compound such as an alkyl ammonium compound. The B-cation 120 may include a metal and the X-anion 130 may include a halogen. Additional examples for the A-cation 110 include organic cations and/or inorganic cations, for example Cs, Rb, K, Na, Li, and/or Fr. Organic A-cations 110 may be an alkyl ammonium cation, for example a C₁₋₂₀ alkyl ammonium cation, a C₁₋₆ alkyl ammonium cation, a C₂₋₆ alkyl ammonium cation, a C₁₋₅ alkyl ammonium cation, a C₁₋₄ alkyl ammonium cation, a C₁₋₃ alkyl ammonium cation, a C₁₋₂ alkyl ammonium cation, and/or a C₁ alkyl ammonium cation. Further examples of organic A-cations 110 include methylammonium (CH₃NH₃⁺), ethylammonium (CH₃CH₂NH₃⁺), propylammonium (CH₃CH₂ CH₂NH₃⁺), butylammonium (CH₃CH₂ CH₂ CH₂NH₃⁺), forma-midinium (NH₂CH═NH₂⁺), hydrazinium, acetylammonium, dimethylammonium, imidazolium, guanidinium, benzylammonium, phenethylammonium, and/or any other suitable nitrogen-containing or organic compound. In other examples, an A-cation 110 may include an alkylamine. Thus, an A-cation 110 may include an organic component with one or more amine groups. For example, an A-cation 110 may be an alkyl diamine halide such as formamidinium (CH(NH₂)₂). Thus, the A-cation 110 may include an organic constituent in combination with a nitrogen constituent. In some cases, the organic constituent may be an alkyl group such as straight-chain or branched saturated hydrocarbon group having from 1 to 20 carbon atoms. In some embodiments, an alkyl group may have from 1 to 6 carbon atoms. Examples of alkyl groups include methyl (C₁), ethyl (C₂), n-propyl (C₃), isopropyl (C₃), n-butyl (C₄), tert-butyl (C₄), sec-butyl (C₄), iso-butyl (C₄), n-pentyl (C₅), 3-pentanyl (C₅), amyl (C₅), neopentyl (C₅), 3-methyl-2-butanyl (C₅), tertiary amyl (C₅), and n-hexyl (C). Additional examples of alkyl groups include n-heptyl (C₇), n-octyl (C₅) and the like.

Examples of metal B-cations 120 include, for example, lead, tin, germanium, and or any other 2+ valence state metal that can charge-balance the perovskite 100. Further examples include transition metals in the 2+ state such as Mn, Mg, Zn, Cd, and/or lanthanides such as Eu. B-cations may also include elements in the 3+ valence state, as described below, including for example, Bi, La, and/or Y. Examples for X-anions 130 include halogens: e.g., fluorine, chlorine, bromine, iodine and/or astatine. In some cases, the perovskite halide may include more than one X-anion 130, for example pairs of halogens; chlorine and iodine, bromine and iodine, and/or any other suitable pairing of halogens. In other cases, the perovskite 100 may include two or more halogens of fluorine, chlorine, bromine, iodine, and/or astatine.

Thus, the A-cation 110, the B-cation 120, and X-anion 130 may be selected within the general formula of ABX₃ to produce a wide variety of perovskites 100, including, for example, methylammonium lead triiodide (CH₃NH₃PbI₃), and mixed halide perovskites such as CH₃NH₃PbI₃₋ₓClₓ and CH₃NH₃PbI₃₋ₓBrₓ. Thus, a perovskite 100 may have more than one halogen element, where the various halogen elements are present in non-integer quantities; e.g., x is not equal to 1, 2, or 3. In addition, perovskite halides, like other organic-inorganic perovskites, can form three-dimensional (3-D), two-dimensional (2-D), one-dimensional (1-D) or zero-dimensional (0-D) networks, possessing the same unit structure. As described herein, the A-cation 110 of a perovskite 100, may include one or more A-cations, for example, one or more of cesium, FA, MA, etc. Similarly, the B-cation 120 of a perovskite 100, may include one or more B-cations, for example, one or more of lead, tin, germanium, etc. Similarly, the X-anion 130 of a perovskite 100 may include one or more anions, for example, one or more halogens (e.g., at least one of I, Br, Cl, and/or F), thiocyanate, and/or sulfur. Any combination is possible provided that the charges balance.

For example, a perovskite having the basic crystal structure illustrated in FIGS. 1A and 1B, in at least one of a cubic, orthorhombic, and/or tetragonal structure, may have other compositions resulting from the combination of the cations having various valence states in addition to the 2+ state and/or 1+ state described above for lead and alkyl ammonium cations; e.g., compositions other than AB²⁺X₃ (where A is one or more cations, or for a mixed perovskite where A is two or more cations). Thus, the methods described herein may be utilized to create novel mixed cation materials having the composition of a double perovskite (elpasolites), A₂B¹⁺B³⁺X₆, with an example of such a composition being Cs₂BiAgCl₆ and Cs₂CuBiI₆. Another example of a composition covered within the scope of the present disclosure is described by A₂B⁴⁺X₆, for example Cs₂PbI₆ and Cs₂SnI₆. Yet another example is described by A₃B₂³⁺X₉, for example Cs₃Sb₂I₉. For each of these examples, A is one or more cations, or for a mixed perovskite, A is two or more cations.

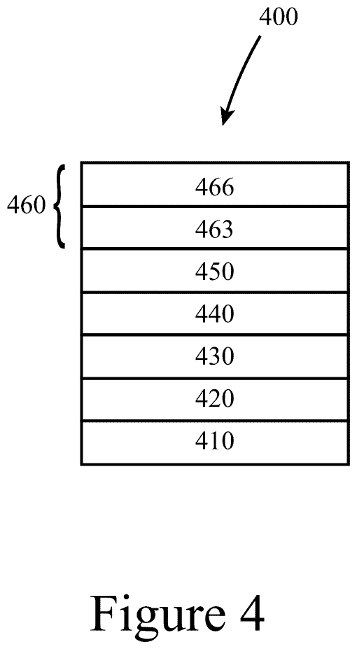

FIG. 4 illustrates an exemplary device 400, according to some embodiments of the present disclosure. As shown herein, a device 400 may include an electrode 460 having a bilayer structure having a first electrode layer 463 (i.e., a metal-doped carbon layer) and a second electrode layer 466 characterized by the use of a low melting temperature metal or alloy, e.g., (<200° C.). As shown herein, such a bilayer electrode 460 may be positioned adjacent to and in contact with a charge transport layer (CTL) 450, for example a CTL made of a hole transport material (HTM) for an n-i-p device or an electron transport material (ETM) for a p-i-n device. Further, a CTL 450 may be positioned between an active layer 440 (e.g., perovskite) and the bilayer electrode 460. Referring again to FIG. 4, a device 400 may also include a substrate 410, a first electrode 420, and first CTL 430, where the first electrode 420 is positioned between the substrate 410 and the first CTL 430. Since this exemplary device 400 contains two electrodes and two CTLs, these are named herein for clarity as first electrode 420 and second electrode 460, and first CTL 420 and second CTL 450, respectively.

In some embodiments of the present disclosure, an HTM used to construct a second CTL 450 may include at least one of a carbon-containing material, a self-assembling molecule, PTAA, nickel oxide, and/or spiro-OMeTAD. In some embodiments of the present disclosure, a device utilizing a bilayer second electrode 460 like those described herein may be an n-i-p device where the second CTL 450 is a HTL with the second electrode 460 deposited thereon. In some embodiments of the present disclosure, a device utilizing a bilayer second electrode 460 like those described herein may be a p-i-n device where the CTL 450 is an electron transport layer (ETL) with the second electrode 460 deposited thereon. In some embodiments of the present disclosure, a carbon-containing material used to construct a hole transport layer (e.g., second CTL 450 for an n-i-p device) may include at least one of graphite, a graphene, a fullerene, an amorphous carbon, and/or a carbon filler. In some embodiments of the present disclosure, a carbon-containing material used in a first layer 463 of a second electrode 460 may include at least one of graphite, carbon-black, and/or a carbon filler. In some embodiments of the present disclosure, where a CTL is constructed using a carbonaceous material, a second electrode 460 may not have a bilayer design and may only have a “second” electrode layer 466 constructed of a low melting temperature metal or alloy.

Thus, an aspect of the present disclosure includes a second CTL 450 constructed of a carbon-containing material and/or carbonaceous material where the second CTL 450 itself may behave as a blocking layer to the transfer of a low melting temperature metal or alloy into the CTL and/or through the CTL. Examples of such carbon-containing materials are listed above for ETMs and include fullerene-based materials and/or their derivatives.

Thus, a device 400 using a non-carbon-containing second CTL 450 may have the following architecture:

$$substrate / {1}^{st} electrode / {1}^{st} CTL / absorber layer / {2}^{nd} CTL / bilayer {2}^{nd} electrode$$

where the bilayer second electrode 460 includes a first electrode layer 463, e.g., a metal-doped or undoped carbon layer (i.e., first layer 463) and a second electrode layer 463, e.g., a low melting temperature metal or alloy, where the first layer 463 prevents the mass-transfer of material from the second layer 463.

However, in some embodiments, where the second CTL 450 is already a sufficient barrier to the transfer of a metal or alloy, e.g., a carbonaceous ETL such as a fullerene, a device 400 may have the following architecture:

$$substrate / {1}^{st} electrode / {1}^{st} CTL / absorber layer / {2}^{n d} CTL / single layer {2}^{n d} electrode$$

where the single layer second electrode 460 only has a second layer 466 constructed of a low melting temperature metal or alloy.

In some embodiments of the present disclosure, the metal of a metal-doped carbon layer (i.e., first layer 463 of a second electrode 460 may include a transition metal. In some embodiments of the present disclosure, the transition metal included in a first layer 463 may include at least one of nickel, cobalt, and/or tungsten. In some embodiments of the present disclosure, a metal present in a first layer 463 may be present at a concentration between greater than 0 wt % and less than 30 wt % or between 5 wt % and 20 wt %. In some embodiments of the present disclosure, the metal in a first electrode layer 463 may be in a particulate form having an average particle size between 10 nm and 10 μm or between 500 nm and 2 μm. In some embodiments of the present disclosure, a metal-doped carbon layer 463 may have a thickness between 0.1 μm and 50 μm or between 0.2 μm and 20 μm.

In some embodiments of the present disclosure, a metal or alloy used to construct a second electrode layer 466 may have a melting point between 100° C. and 200° C. In some embodiments of the present disclosure, an alloy used to construct a second electrode layer 466 may include low melting point metals that includes at least two of indium, bismuth, tin, antimony, gallium, and/or zinc. In some embodiments of the present disclosure, an alloy used to construct a second electrode layer 466 of a second electrode 460 may include bismuth and indium. In some embodiments of the present disclosure, bismuth present in a second electrode layer 466 may be present at a concentration between greater than 5 wt % and less than 95 wt %, or between 40 wt % and 60 wt %. In some embodiments of the present disclosure, a second electrode layer 466 may have a thickness between 0.1 μm and 50 μm, or between 1 μm and 10 μm.

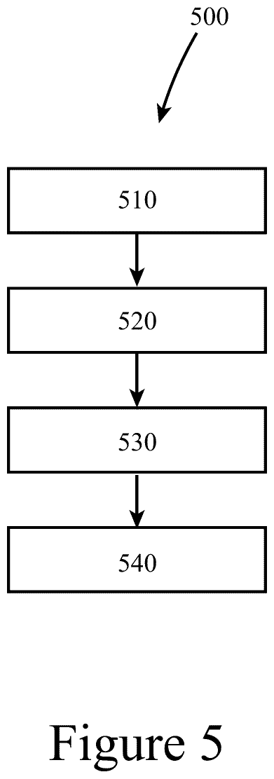

FIG. 5 illustrates an exemplary method 500 for constructing a device 400 like that illustrated in FIG. 4, according to some embodiments of the present disclosure. As shown herein, such a method 400 may include synthesizing metal particles 510, synthesizing a carbon-metal mixture 520 that includes the metal particles and a carbon-containing material, applying the carbon-metal mixture 530 to a device stack that includes a CTL and a perovskite layer, resulting in the forming of a layer that includes the carbon-containing material and the metal particles (i.e., a first layer 463 of a bilayer electrode 460), followed by the applying of a low melting temperature metal or alloy in liquid form to a surface of the layer of the carbon-containing material and the metal particles, resulting in the forming a second layer 466 of a bilayer electrode 460.

In some embodiments of the present disclosure, a method 400 may not include at least one of the steps of synthesizing metal particles 510, synthesizing a carbon-metal mixture 520, and/or applying a carbon-metal mixture 530. In some embodiments of the present disclosure, a method 400 may begin the applying of a carbon-metal mixture 530, followed by the applying of an alloy 540. Further, in some embodiments of the present disclosure, a method 400 may not include each of the steps of synthesizing metal particles 510, synthesizing a carbon-metal mixture 520, and applying a carbon-metal mixture 530, such that the method only including the step of applying an allow 540 to a CTL, resulting in a device 400 having a second electrode 460 that is absent of a first electrode layer 463 (e.g., a metal-doped graphite layer) and only include a second electrode layer 460, constructed of a low melting temperature metal or alloy (e.g., bismuth and/or indium).

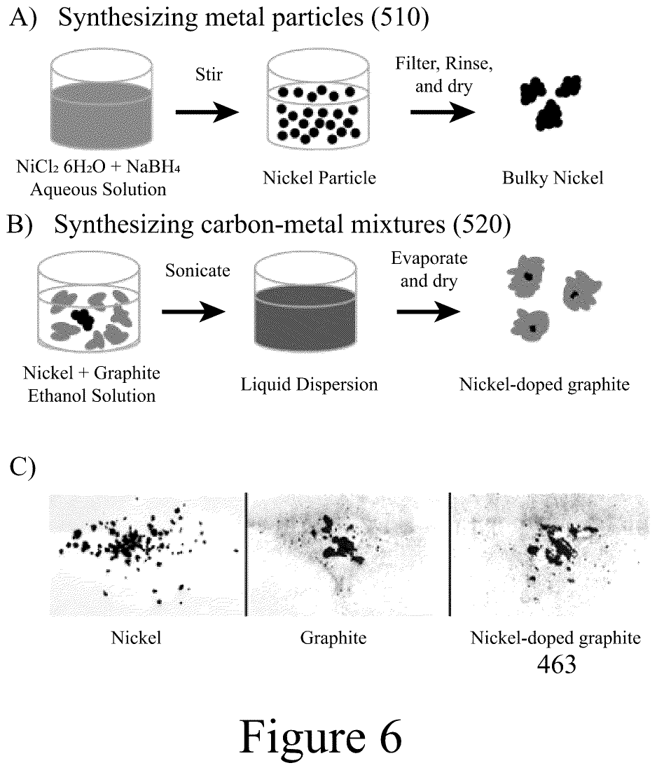

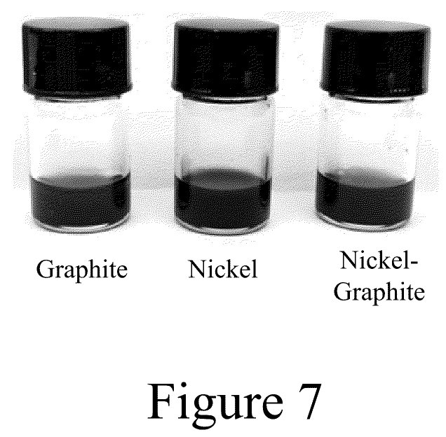

Panels A and B of FIG. 6 illustrate aspects of an exemplary method 500 for making devices as described herein, according to some embodiments of the present disclosure. Panel C of FIG. 6 illustrates photos of nickel microparticles having a particle size range between 10 nm and 100 nm, natural graphite in the form of flakes having a characteristic width between 100 nm and 100 μm or between 100 nm and 50 μm, and nickel-doped graphite. Referring to Panel A of FIG. 6, the synthesizing of metal particles 510 began with the addition of about 200 mL of ultrapure water to a beaker with 5.0 g NiCl₂·6H₂O, which was then stirred to obtain a transparent green solution. Next, 300 mg of NaBH₄ was added into the NiCl₂ solution in batches. Black nickel particles immediately precipitated with vigorous effervescence. Stirring continued for 5 minutes. Then, another 300 mg of NaBH₄ was added into the solution and stirred for another 5 minutes. For the complete reduction of Ni²⁺ to Ni⁰, another 400 mg of NaBH₄ was added into the solution under stirring for about 30 minutes. The precipitated black nickel particles were collected by filtration, and at least 400 mL of ultrapure water was used to rinse the nickel particles 10 times. Finally, the collected Ni particles were put on the hot plate for desiccation at 110° C. for 2 hours, thus concluding the step of synthesizing metal particles 510. Panel B of FIG. 6 illustrates the synthesizing of carbon-metal mixtures 520, in this example, the synthesis of nickel-doped graphite. This was completed as follows. About 10 mg of dried Ni nanoparticles and 100 mg of natural graphite flake were added to a 20-mL vial with 6 mL of anhydrous ethanol. This was then sonicated for 30 minutes for dispersion and mixing. The suspension was then poured into a weighing bowl and put on the hot plate for desiccation at 110° C. for 1 hour. Panel C of FIG. 6 illustrates photos of resultant nickel and nickel-doped graphite, as well as starting graphite used to synthesize the nickel-doped graphite. Nickel microparticles, graphite flakes, and nickel-doped graphite powder were then successfully dispersed in ethanol using ultrasound resulting in stable suspensions (see FIG. 7).

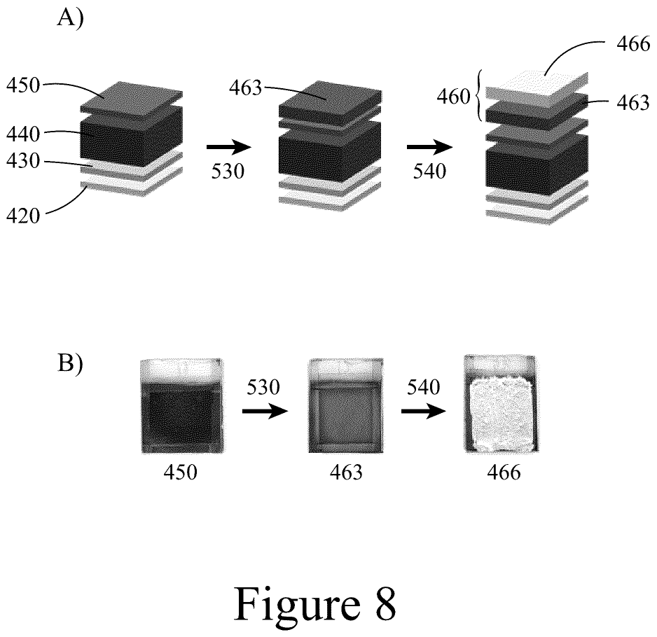

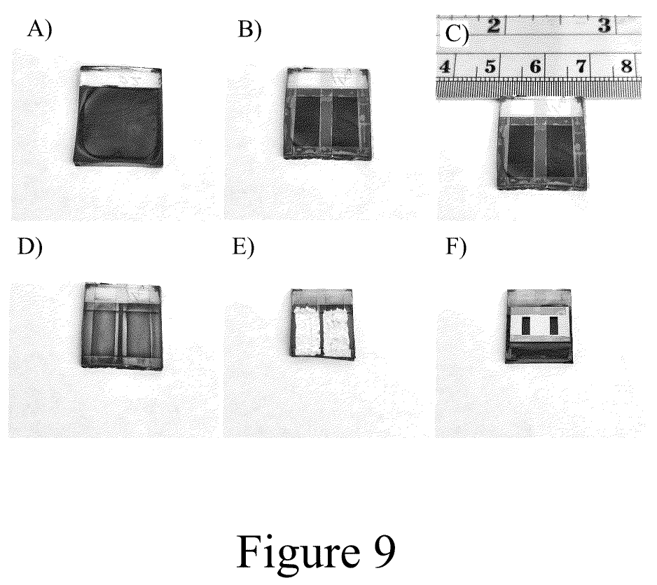

A laboratory-scale method of coating graphite and/or a Ni-doped graphite layer (i.e., metal-doped carbon layer first layer 463) was performed as follows. The tip of a foam swab was covered with graphite and/or Ni-G, and then the graphite and/or Ni-G was applied to the surface of a spiro-OMeTAD layer (i.e., a second CTL 450) by rubbing the swab onto the surface of the CTL 450 (see Panel A of FIG. 8). The graphite and/or Ni-G transferred from the swab and attached to the spiro-OMeTAD layer (second CTL 450) due to the mechanical lubricity of graphite materials (e.g., pure graphite and/or metal-doped graphite), resulting in the forming of a first layer 463. Next, a Bi—In alloy consisting of 50 wt % bismuth and 50 wt % indium was prepared with a melting point of 89.5° C. This alloy was laminated onto the graphite layer using a paint brush fully stained with melted alloy (see Panel B of FIG. 8), and the size of devices was defined using a mask of Kapton tape, as illustrated in FIG. 9). The alloy layer solidified when the PSC device was removed from the hot plate, resulting in the formation of a second layer 466 (i.e., alloy layer).

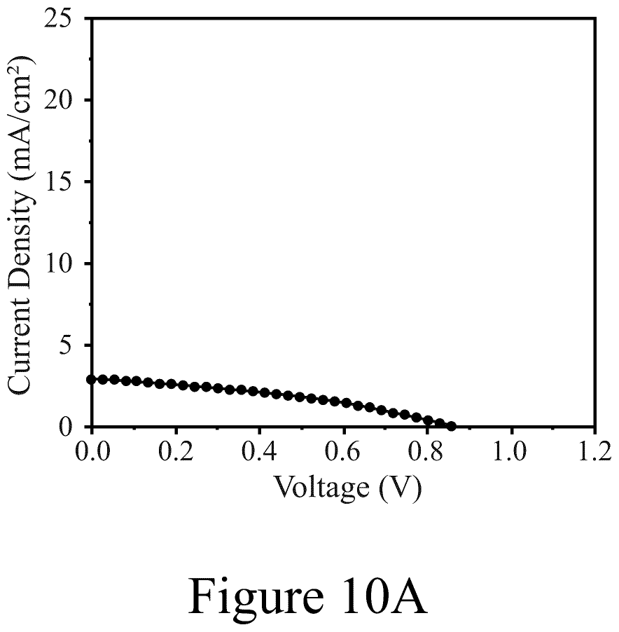

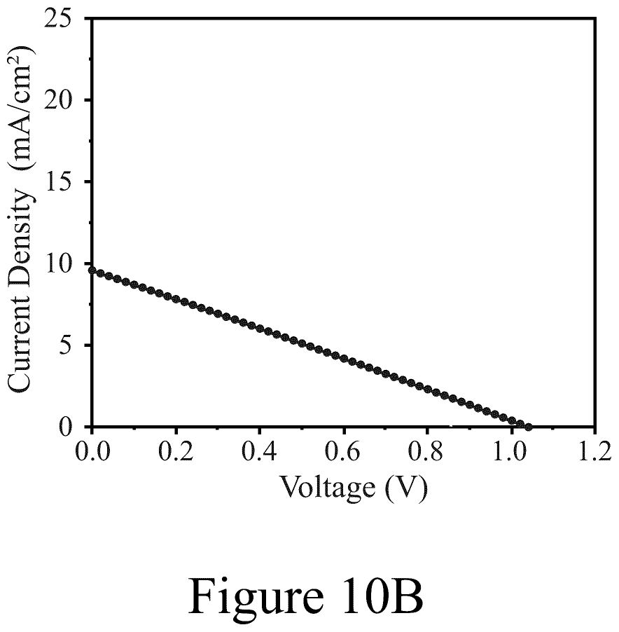

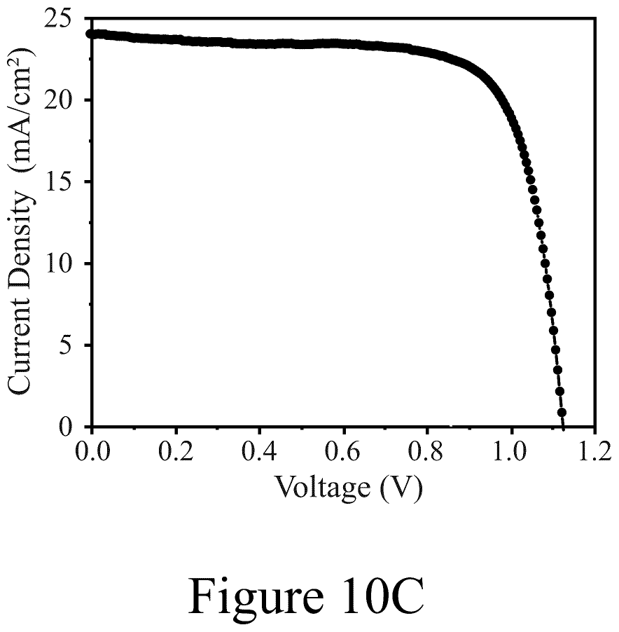

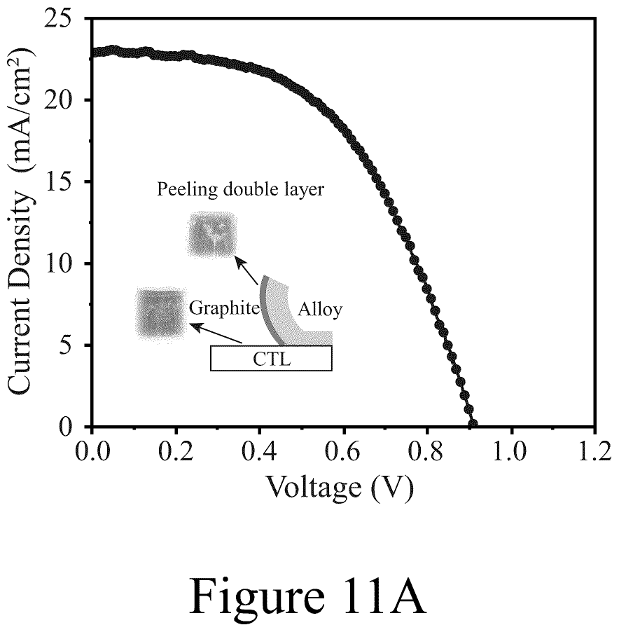

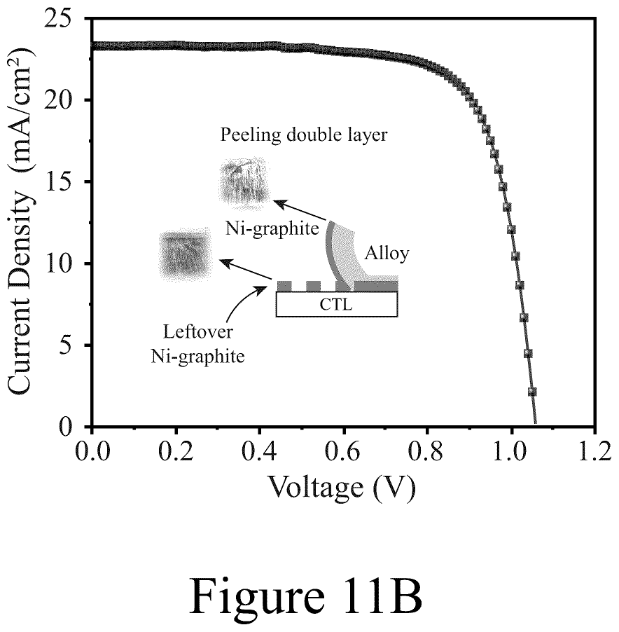

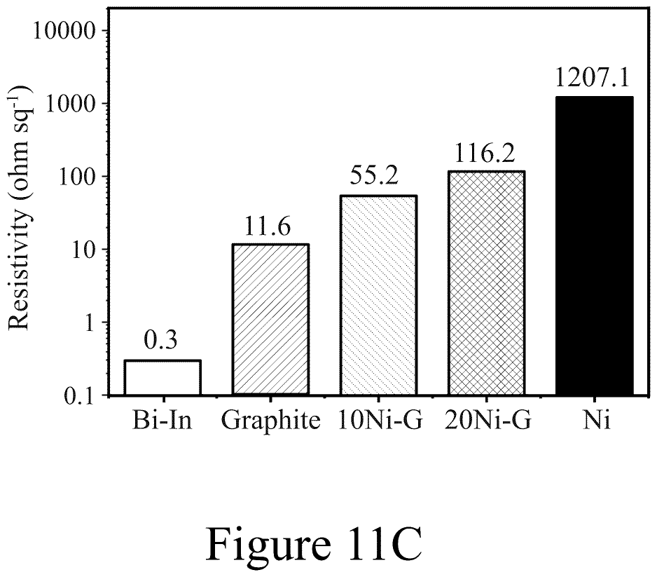

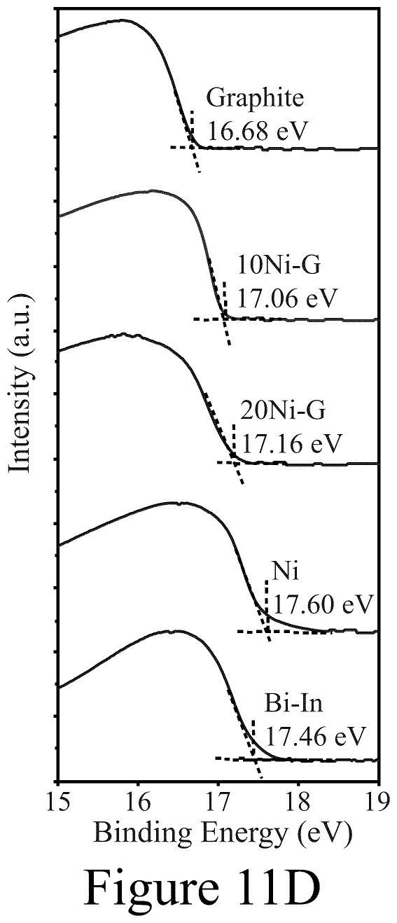

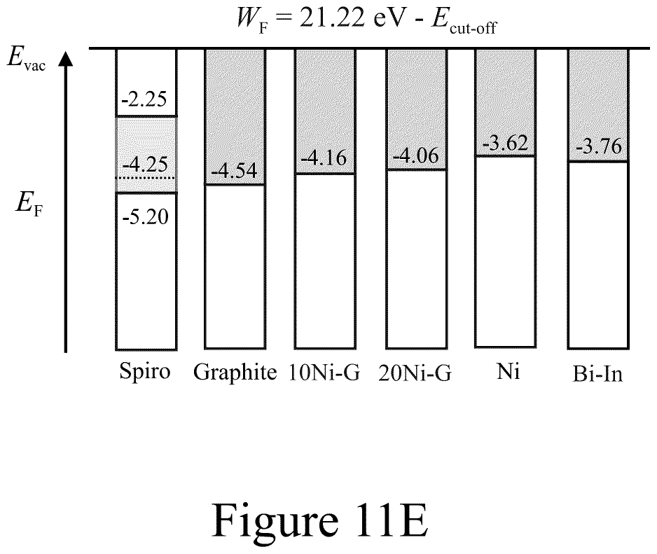

Exemplary FA_{0.85}MA_{0.1}Cs_{0.05}Pb(I_{0.9}Br_{0.1})₃-based PSCs were prepared to evaluate the PV performance with different second electrodes. For comparison, single layer second electrodes 460 were tested: an second electrode having just a second electrode layer 466 constructed of a Bi—In alloy (50-50 wt %) and a second electrode constructed using a first electrode layer 463 of pure undoped graphite layer. Devices utilizing a single layer second electrode 460 having just a second layer 466 or just a first layer 463 with the compositions defined above demonstrated PCEs of 0.9% and 2.6%, respectively (see FIGS. 10A and 10B). A similar PSC device stack using gold as an electrode demonstrated a PCE of 20.1% (see FIG. 10C). FIGS. 11A and 11B illustrate the current density-voltage (J-V) curves of PSCs using either a bilayer second electrode 460 constructed of an undoped graphite (G) layer (i.e., a non-metal doped carbon first electrode layer 463 and a Bi—In alloy second electrode layer 466 versus using a bilayer second electrode 460 constructed using a 10 wt % Ni-doped graphite (10Ni-G) first electrode layer 463 and a Bi—In second electrode layer 466. In stark contrast to the PSCs using just a Bi—In alloy layer (just a second electrode layer 466) or just a pure graphite layer (an undoped carbon first electrode layer 463) as second electrodes 460 (each layer tested by itself; not in combination to form a bilayer second electrode 460), the PSCs using either a G/Bi—In (first electrode layer 463/second electrode layer 466) bilayer second electrode 460 or a 10Ni-G/Bi-(first layer 463/second layer 466) bilayer second electrode 460 exhibited greatly enhanced values for PCE, 11.0% and 18.3%, respectively.

To gain further insight from the PCE data, four-probe measurements were carried out to examine the conductivity of the electrode materials described above on devices having the same device architecture as illustrated in Panel A of FIG. 8. As FIG. 11C illustrates, the sheet resistances of a single Bi—In alloy layer (i.e., second electrode layer 466) and a single undoped graphite layer (undoped first electrode layer 463) were 0.3 Ω sq⁻¹ and 11.6 Ω sq⁻¹, respectively. The PSC devices based on undoped graphite layer (i.e., undoped first electrode layer 463) alone (i.e., in the absence of a Bi—In alloy second electrode layer 466) exhibited a low PCE of 2.6%, partly due to the higher resistivity of undoped graphite compared to the resistivity of Bi—In alloy. Furthermore, an ultraviolet photoelectron spectroscopy (UPS) study was conducted to obtain the work function (WF) of these materials (see FIG. 11D). FIG. 11E illustrates a comparison of the Fermi energy level of spiro-OMeTAD (−4.25 eV) with the WF of graphite, 10 wt % Ni-doped graphite (10Ni-G), 20 wt % Ni-doped graphite (20Ni-G), nickel (Ni) microparticles, and Bi—In alloy, which are −4.54 eV, −4.16 eV, −4.06 eV, −3.62 eV, and −3.76 eV, respectively. These data show that although the Bi—In alloy has better electrical conductivity than undoped graphite, and the mismatch between the WF of the Bi—In alloy and the Fermi level of the HTL (spiro-OMeTAD) resulted in the poor PCE.

It is therefore evident that simultaneously obtaining proper WF and lower serial resistance is key to designing a back electrode that can result in a device having a high PCE, as exemplified by the bilayer electrode made from graphite/Bi—In (first electrode layer 463/second electrode layer 466) and Ni-G/Bi—In (first electrode layer 463/second electrode layer 466). It is still desirable to further fine-tune the WF of graphite, because the V_{oc} of the PSC using the G/Bi—In (first electrode layer 463/second electrode layer 466) bilayer electrode is still only 0.91 V. This is likely due to the transfer of Bi—In alloy from the second electrode layer 466 through the graphite layer (undoped first second layer 463) resulting in contact with the underlying HTL (i.e., second CTL 450), as illustrated in the inset of FIG. 11A. The entire graphite first electrode layer 463 was penetrated by the Bi—In alloy material from the second electrode layer 466, such that when the graphite layer was peeled off, almost all of the graphite was removed from the underlying surface of the second CTL 450, which in this example, was constructed of spiro-OMeTAD.

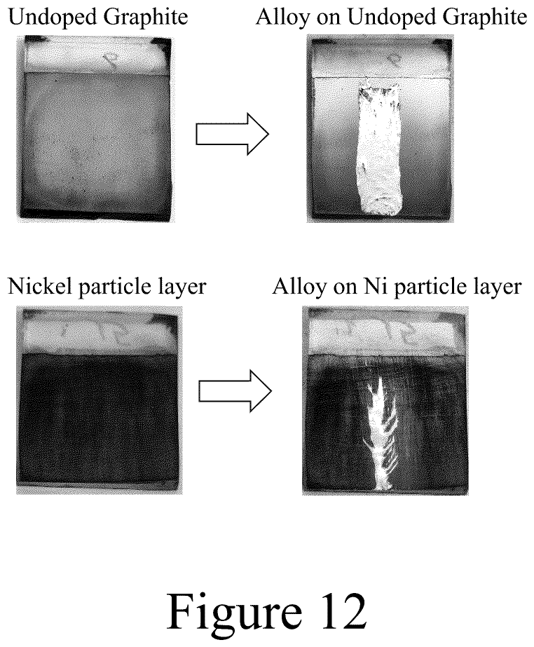

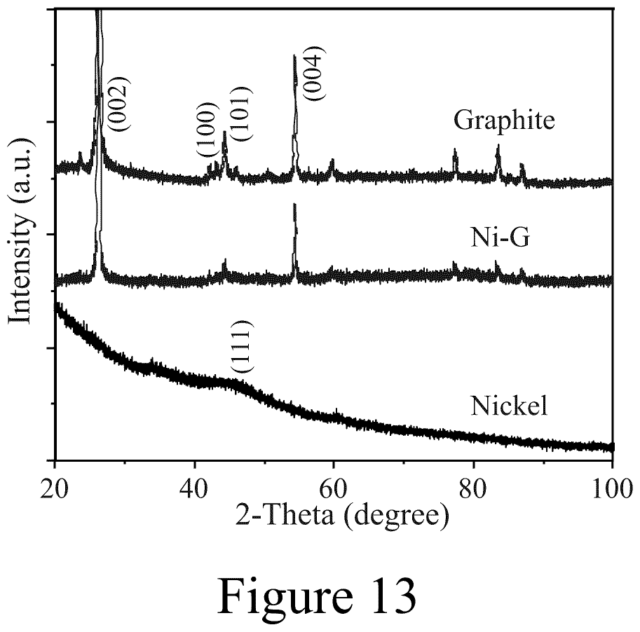

To enhance the resistance of a graphite first electrode layer 463 to Bi—In alloy ingression from a second electrode layer 466, nickel microparticles were introduced as a dopant into the graphite, because nickel is impermeable to this alloy (see FIG. 12). In addition, this dopant also contributes to the alignment of the back electrode's WF with the Fermi level of spiro-OMeTAD (−4.25 eV). Bulk crystalline nickel has a WF of 5.04 eV, and graphite has a WF of 4.54 eV. Thus, an amorphous Ni powder was used (evidenced by X-ray diffraction, as illustrated in FIG. 13) with a reduced WF as the dopant so that the overall WF of Ni-doped graphite for use in a first electrode layer 463 of a bilayer second electrode 460 was in alignment with the Fermi level of a second CTL 450 constructed of spiro-OMeTAD (see FIG. 11E). By balancing the resistivity and the WF, a concentration of Ni particles in graphite of about 10 wt % was determined to be a best concentration for producing a first electrode layer 463 for use in a bilayer second electrode 460 in a device stack using spiro-OMeTAD as the hole-transfer material in a second CTL 250. In some embodiments of the present disclosure, for an n-i-p device, the difference between the work function of the material making up a second electrode 460 and the Fermi level of the second CTL 450, in this example an HTL, as defined by WF(metal)—Femi level (HTL), may be between 0.05 eV and 0.6 eV or between 0.1 eV and 0.3 eV. In some embodiments of the present disclosure, for an n-i-p device, the difference between the Fermi level of the second CTL 450 and the work function of the material making up the second electrode 460, in this example an ETL, as defined by Femi level (ETL)—WF(metal), may be between 0.05 eV and 0.6 eV or between 0.1 eV and 0.3 eV.

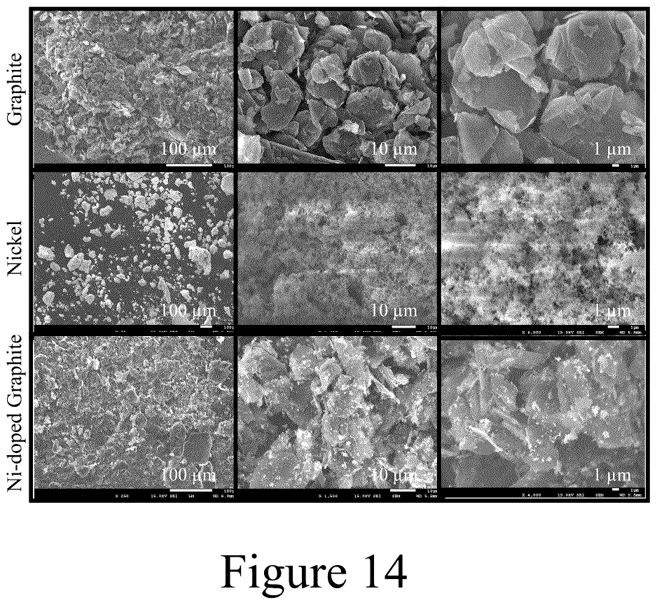

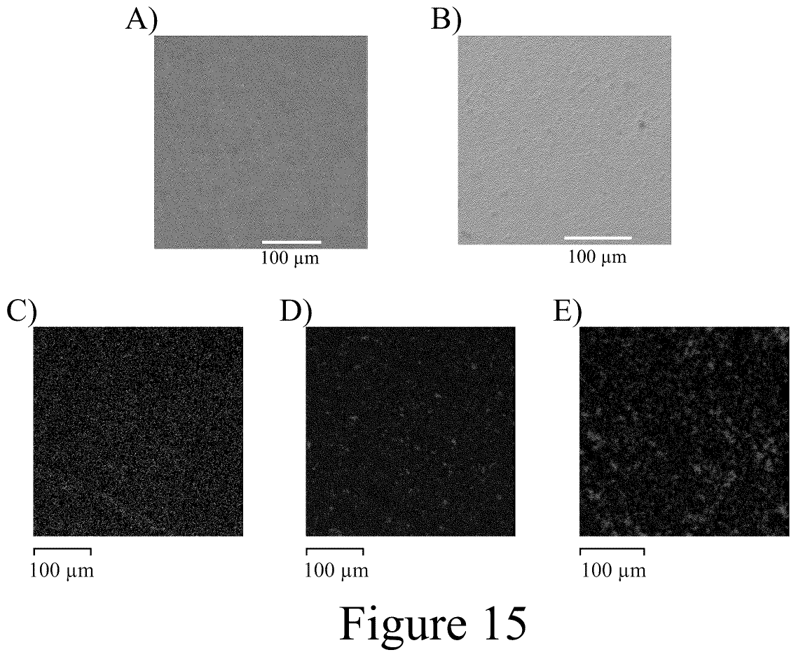

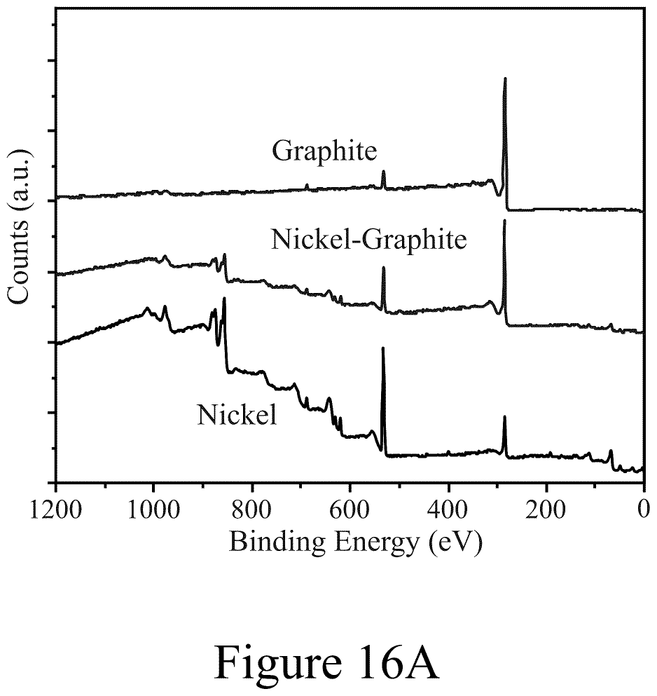

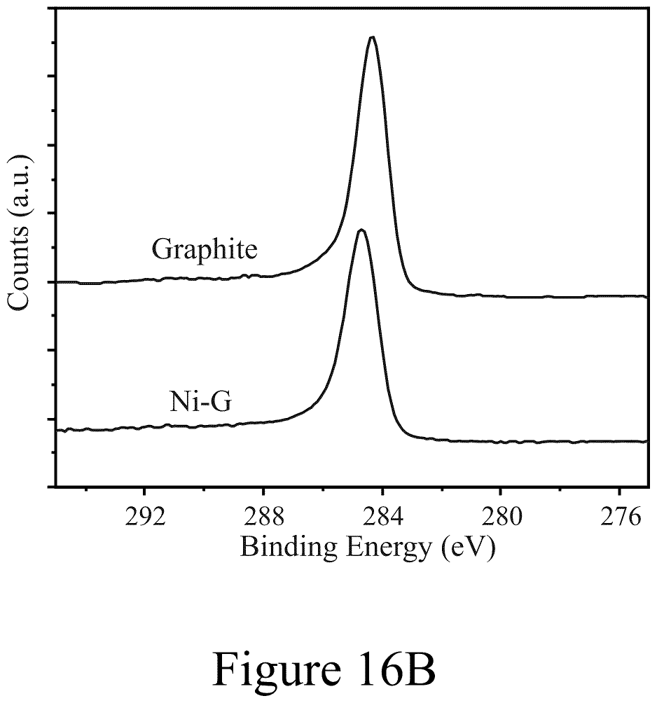

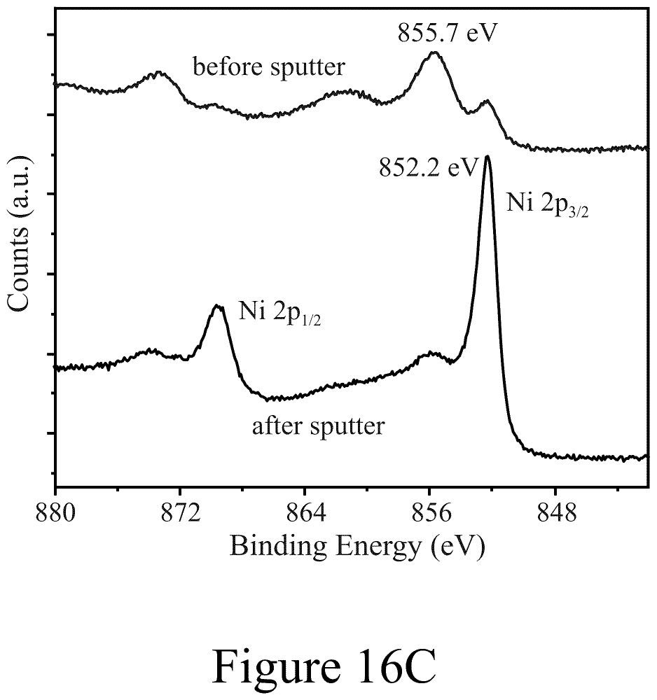

The morphology of nickel powder and natural graphite mixtures were studied via scanning electron microscope (SEM), showing a mixture of dots with sizes in the sub-micrometer range (between 10 nm and 500 nm) and flakes with sizes between 0.1 μm and 100 μm (see FIG. 14). The uniformity of the Ni doping was evaluated via energy-dispersive X-ray (EDX) analysis, as illustrated in FIG. 15, which shows a homogeneous dispersion of Ni in graphite. X-ray photoelectron spectroscopy (XPS) study indicates that the Ni particles have a binding energy of 852.2 eV, in agreement with metallic nickel after removing a thin surface oxide layer by Ar⁺ milling (see FIGS. 16A and 16B). As a result, the alloy does not wet through the nickel microparticle-doped graphite layer, leaving only graphite powders on the spiro-OMeTAD surface upon peeling off the alloy layer as illustrated in the inset of FIG. 11B.

Table 1 summarizes the PV performance data of various PSCs with different back electrodes (i.e., second electrodes 460) tested herein. The PSC device using 10 wt % Ni-doped graphite (10Ni-G)/alloy (50 wt % Bi and 50 wt % In) (first layer 463/second layer 466) bilayer second electrode 460 exhibited the best performance, with a short-circuit current density (J_{sc}) of 23.3 mA·cm², open-circuit voltage (V_{oc}) of 1.06 V, fill factor (FF) of 0.74, and PCE of 18.3%.

TABLE 1
Photovoltaic parameters of PSC devices based on back electrodes with structures of
alloy only, undoped graphite only, undoped graphite/alloy, 10 wt % Ni-doped graphite/alloy,
20 wt % Ni-doped graphite/alloy, Ni/graphite/alloy, and Au, respectively.

| Back Electrode | J_{sc} (mA · cm⁻²) | Voc (V) | FF | PCE (%) |
|---|---|---|---|---|
| Alloy (50 wt % of Bi | 2.9 | 0.86 | 0.35 | 0.9 |
| and 50 wt % of In) | | | | |
| G | 9.5 | 1.04 | 0.26 | 2.6 |
| G/alloy bilayer | 22.9 | 0.91 | 0.53 | 11.0 |
| 10Ni-G/alloy bilayer | 23.3 | 1.06 | 0.74 | 18.3 |
| 20Ni-G/alloy bilayer | 21.4 | 1.03 | 0.67 | 14.8 |
| Au | 24.0 | 1.12 | 0.75 | 20.1 |

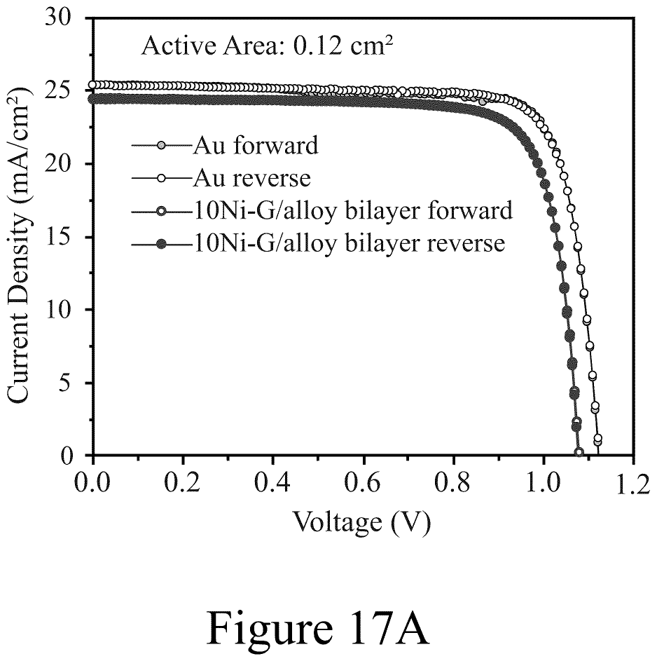

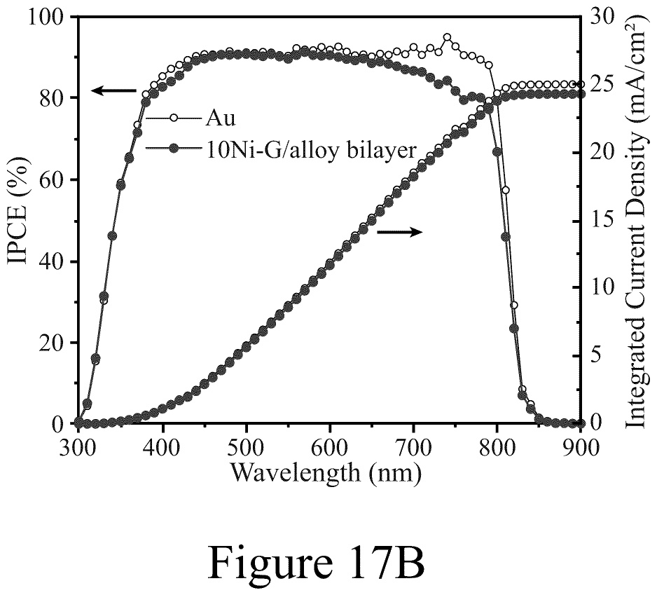

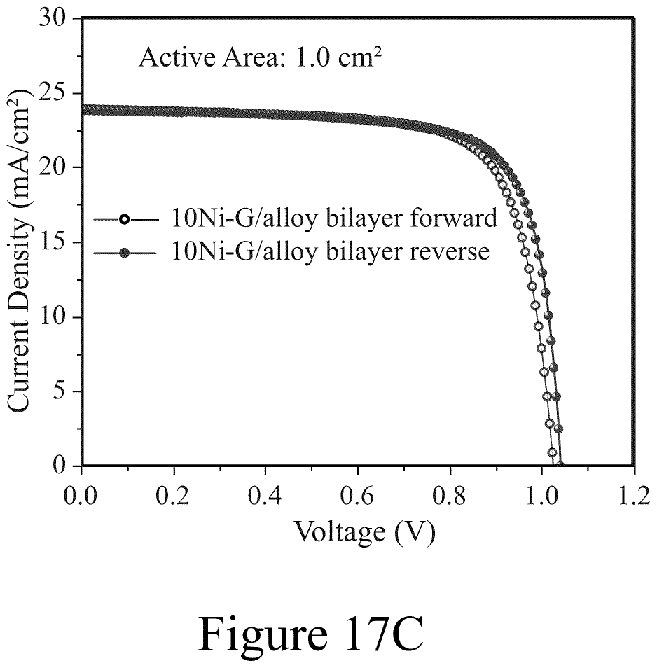

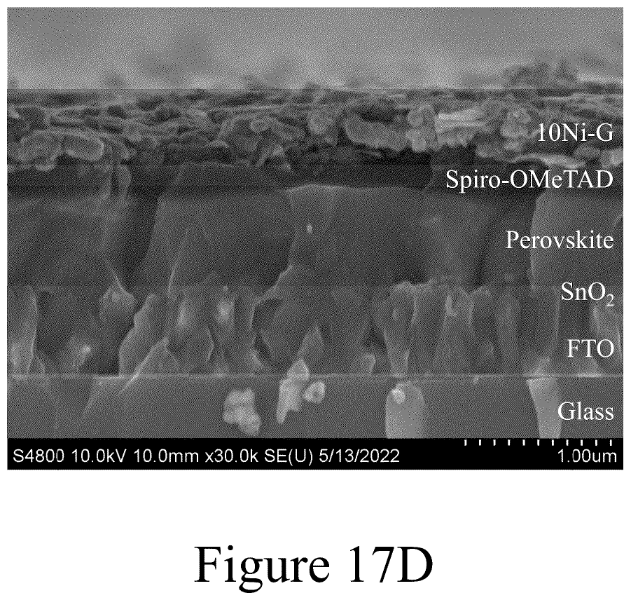

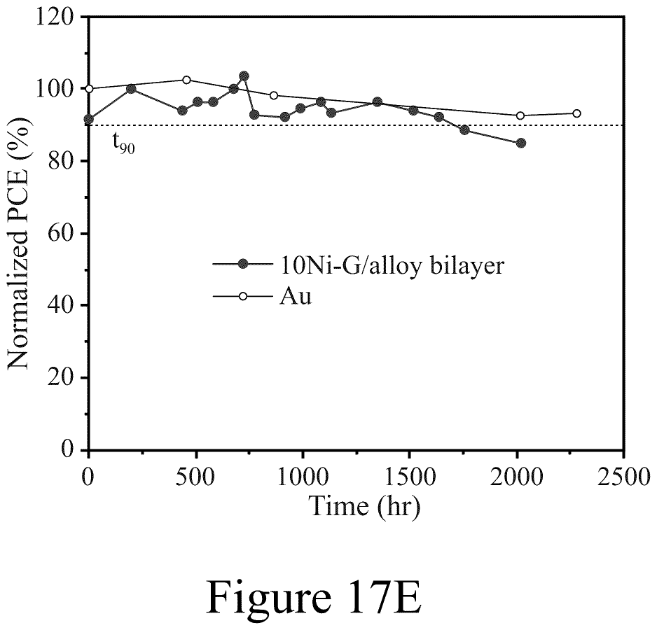

To further explore the potential of 10Ni-G/alloy bilayer electrodes in high-performance PSCs, PSCs were constructed using a FAPbI₃-based perovskite absorber and a device architecture like that illustrated in FIG. 8. FIG. 17A illustrates the 10Ni-G/alloy-based PSC with an active area of 0.12 cm² exhibiting a J_{sc} of 24.4 mA·cm⁻², V_{oc} of 1.08 V, FF of 0.79, and PCE of 21.0%. Its gold-based counterpart PSC exhibited a PCE of 22.8%. FIG. 17B illustrates the corresponding incident photon to current efficiency (IPCE) spectra and integrated current density of PSCs with a 10Ni-G/alloy bilayer second electrode 460 and a vacuum-evaporated Au layer as a second electrode 460, respectively. Both the IPCE spectra and integrated current density are in good agreement with their respective J_{sc} values. In addition, the fact that the sheet resistance of the Bi—In alloy layer (0.3 Ω/sq) is much less than that of FTO (~10 Ω/sq) allows us to achieve large device sizes with compatible PCE. Thus, 10Ni-G/alloy-based PSC devices with a large active area of 1 cm² were also constructed; these devices exhibited a PCE of 18.7% (see FIG. 17C). The detailed PV parameters of these devices are summarized in Table 2.

TABLE 2
PV parameters (reverse scan) of PSC devices based on 10Ni-G/alloy with small
active area (0.12 cm2), 10Ni-G/alloy with large active area (1 cm2), and gold with small
active area (0.12 cm2).

| Back Electrode | Area (cm²) | J_{sc} (mA · cm⁻²) | Voc (V) | FF | PCE (%) |
|---|---|---|---|---|---|
| 10Ni-G/alloy | 0.12 | 24.4 | 1.08 | 0.79 | 21.0 |
| 10Ni-G/alloy | 1.0 | 23.9 | 1.04 | 0.75 | 18.7 |
| Au | 0.12 | 25.4 | 1.13 | 0.80 | 22.8 |

FIG. 17D illustrates the cross-sectional SEM image of the FAPbI₃-based PSC using 10Ni-G as the second electrode 460 and a device architecture like that illustrated in FIG. 8. Note that the second electrode layer 466 is not visible in this example, as it was too ductile to define a sharp edge for SEM evaluation. FIG. 17E illustrates a comparison of the ambient storage stability of PSCs based on 10Ni-G bilayer/Bi—In bilayer electrode and gold back electrodes, with an average relative humidity in the range of ~40%-50%. Note that the gold-electrode-based PSC was encapsulated to prevent moisture uptake. In contrast, the 10Ni-G/Bi—In bilayer electrode-based PSC was not encapsulated, as the 10Ni-G bilayer is so dense that it provides effective encapsulation on its own, without any additional encapsulation layer needed, for mitigating moisture ingress. The 10Ni-G/alloy device maintained 85% of its initial efficiency (T₈₅) for more than 2,000 hours, only slightly shorter than the T₉₀=2,282 hours for the gold-based encapsulated device.

### EXPERIMENTAL

Materials: All chemicals used in this work are commercially available, except where indicated otherwise. N,N-dimethylformamide (DMF), dimethyl sulfoxide (DMSO), chlorobenzene (CB), tin(II) chloride dihydrate (SnCl₂·2H₂O, 99.99%), urea, thioglycolic acid (TGA), hydrochloric acid (HCl, 37%), 4-tert-butylpyridine (tBP), acetonitrile (ACN), methylammonium bromide (MABr), 2,2′,7,7′-Tetrakis(N,N-dip-methoxylphenylamine)-9,9′-spirobifluorene (spiro-OMeTAD, SHT-263), nickel dichloride hexahydrate (NiCl₂·6H₂O), sodium borohydride (NaBH₄), and FK209 Co(III) TFSI salt were purchased from Sigma-Aldrich. Bis(trifluoromethane)sulfonimide lithium salt (Li-TFSI), cesium iodide (CsI), lead iodide (PbI₂), and lead bromide (PbBr₂) were purchased from TCI America. Formamidinium iodide (FAI) was purchased from Greatcell Solar. FTO (TEC 7) glass was purchased from NSG Pilkington. Natural graphite flake (325 mesh, 99.8%) was purchased from Alfa Aesar. Kapton tapes, foam swabs, and paint brushes were purchased from Amazon.

Synthesis of nickel nanoparticles: 200 mL of ultrapure water was added to a beaker with 5 g NiCl₂·6H₂O and stirred to obtain a transparent green solution. Then, 300 mg of NaBH₄ was carefully added into the NiCl₂ solution in batches. Black nickel particles immediately precipitated with vigorous effervescence. Stirring was maintained for 5 minutes. Then, another 300 mg of NaBH₄ was added into the solution and stirred for another 5 minutes. For the complete reduction of Ni²⁺ to Ni⁰, 400 mg of NaBH₄ was added into the solution under stirring for at least 30 minutes. The precipitated black nickel particles were collected by filtration, and at least total 400 mL of ultrapure water was used to rinse nickel particles ten times. Finally, the collected nickel particles were put on the hot plate for desiccation at 110° C. for 2 hours.

Preparation of 10 wt % nickel-doped graphite (for first layer 463 of a second electrode 460): 10 mg of dried nickel nanoparticles and 100 mg of natural graphite flake were added into a 20-mL vial with 6 mL of anhydrous ethanol. Ultrasonic treatment for 30 minutes was employed for dispersion and mixing. The suspension was poured into a weighing bowl and put on the hot plate for desiccation at 110° C. for 1 hour.

Preparation of bismuth-indium (Bi—In) alloy (for second layer 466 of a second electrode 460): Bismuth and indium metals of exactly the same weight were added into the Ni crucible. The crucible was heated to 200° C. for the indium to melt. A wood stick was used to stir the melting indium to dissolve the bismuth solid. When all metals formed a homogeneous liquid phase, the hot plate was turned off. The Bi—In alloy ingot was obtained after cooling down to room temperature.

Device Fabrication: FTO substrates were chemically etched with zinc power and dilute HCl solution. Then, the etched FTO substrates were ultrasonically cleaned with a detergent solution made from Hellmanex detergent concentrate and deionized water. Next, deionized water was used to repeatedly rinse the FTO glass to remove residual detergent solution. The FTO glass was dried using hot air gun. Kapton tape was stuck on the counter electrode part of the FTO to avoid further SnO₂ deposition. All FTO substrates were vertically placed on the customized Polytetrafluoroethylene (PTFE) holder, and the holder was put in a glass container. The PTFE holder and glass container must be ultrasonically cleaned by a concentrated KOH aqueous solution in advance to remove all the precipitated contaminants from previous SnO₂ deposition reactions. Those contaminants would be severely detrimental to subsequent SnO₂ deposition and would cause poor device performance. For the SnO₂ deposition, the chemical bath deposition (CBD) method¹ was slightly modified. 6.25 g of urea was added into a glass bottle with 500 mL of ultrapure water. After the solution was stirred to be entirely clear, 1.36 g of SnCl₂·2H₂O was added into the glass bottle. The solution initially became turbid because SnCl₂·2H₂O hydrolyzed in the alkaline aqueous solution. After the solution was stirred and turned into a stable, semitransparent colloidal solution (about 2 minutes), a total of 6.25 mL of 37% concentrated HCl was added into the colloidal solution to dissolve all the precipitate. Finally, 125 μL of TGA was added to this transparent solution. Stirring was maintained for about 2 minutes, and then the solution was poured into the glass container with FTO substrates. A hot plate was used to heat the glass container at 160° C. for 4 hours to achieve CBD SnO₂ ETL deposition. The temperature of the precursor solution was over 90° C. After the reaction, the SnO₂-deposited FTO substrates were ultrasonically cleaned by deionized water repeatedly. Water on the deposited FTO glass was blown away by a hot air gun. The deposited FTO substrates were placed on the hot plate to anneal for 1 hour at 170° C.

To fabricate the perovskite active layer with the composition of (FA_{0.85}MA_{0.1}Cs_{0.05})Pb(I_{0.9}Br_{0.1})₃, a perovskite precursor solution was prepared by dissolving FAI (205 mg, 1.19 M), MABr (16 mg, 0.14 M), CsI (18 mg, 0.07 M), PbBr₂ (51 mg, 0.14 M), and PbI₂ (599 mg, 1.3 M) in the solvent, a mixture of 800 μL of DMF and 240 μL of DMSO. Then, 30 μL of perovskite precursor solution was dripped onto the SnO₂ substrate. To prepare the FAPbI₃-based perovskite precursor solution with 3% MAPBr₃ additive, 1.6 M FAPbI₃ perovskite precursor was prepared by mixing 1.6 M FAI and 1.6 M PbI₂ with 3 mol % MAPbBr₃ and 35 mol % MACl in a mixed solution of DMF and DMSO (8:1 v/v). The perovskite layer was deposited by a two-step spin coating procedure at 2,000 rpm (ramp: 200 rpm/s) and 6,000 rpm (ramp: 2,000 rpm/s) for 10 s and 20 s, respectively. At the last 6 s of the second step, 120 L of chlorobenzene (CB) was dripped onto the perovskite surface within 1.5 s. The perovskite layer gradually turned brown after CB dripping. The substrate was immediately put on a hot plate to anneal at 120° C. for 20 minutes. To prepare the spiro-OMeTAD precursor solution, 86 mg of spiro-OMeTAD was dissolved in 1 mL of CB. Then, 34.15 μL of tBP, 19.44 μL of Li-TFSI ACN solution (1.8 M, 520 mg in 1 mL ACN), and 10.5 μL of FK209 Co(III) TFSI ACN solution (0.2 M, 300 mg in 1 mL ACN) were added into the spiro-OMeTAD CB solution accordingly. 30 μL of spiro-OMeTAD precursor solution was dripped onto the perovskite layer; the spiro-OMeTAD layer was deposited by a spin coating procedure at 4,000 rpm (ramp: 2,000 rpm/s) for 20 s. Before coating the bilayer back electrode, the substrates were placed in dry ambient environment for at least 24 hours for the oxidation of the spiro-OMeTAD layer with the oxygen in air.

Before coating the bilayer back electrode, Kapton tape was applied onto the edges of the spiro-OMeTAD film to avoid a short circuit. Then, Kapton tape of 3-mm width was stuck precisely down the middle of the whole area, dividing the surface into two separate areas. In this way, two independent subcells were obtained on one device. Photos of the substrates with a scaled ruler for reference were taken to calculate the active area (the area was calculated by measuring the pixel and comparing the pixel area with the scale of the ruler). For the fixed aperture area of 0.1 cm², a shadow mask with two separate aperture areas was stuck on the glass side of the device. Foam swabs were fully stained with graphite powders, Ni-doped graphite powders, or nickel powders. Then, the powders were scratched onto the spiro-OMeTAD surface—lightly at first, and then more strongly—until the compact surface was observed (except for scratching nickel powder). Note that the graphite layers of the two separate areas should not cross over to each other. A small piece of glass can cover one area when scratching graphite powder onto another area. After fabricating an Ni-doped graphite or nickel layer, a foam swab was stained with pure graphite and scratched it onto the Ni-doped graphite or nickel surface because nickel is not affinitive with Bi—In alloy. It is necessary to coat pure graphite before brushing Bi—In alloy because pure graphite can greatly improve the wettability of Bi—In alloy. Finally, the graphite-coated devices were placed on the hot plate at 110° C. A paintbrush was fully stained with melting Bi—In alloy, which was then brushed onto the graphite surface. After brushing, the device was continuously heated for about 1 minute and then taken onto the cool plate for the alloy to solidify. Similarly, the alloy layers of the two separate areas should not cross over to each other. Polydimethylsiloxane (PDMS) silicone elastomer (Sylgard 184) and its corresponding curing agent were used in a volume ratio of 10:1 to encapsulate the devices.

### Characterization:

X-ray photoelectron spectroscopy (XPS) was conducted in a PHI 5000 VersaProbe II system (Physical Electronics) attached to an Ar-atmosphere glovebox. The spectra were obtained using an Al Kα radiation (hν=1486.6 eV) beam (100 μm, 25 W), with Ar+ and electron beam sample neutralization, in a fixed analyzer transmission mode. Ultraviolet photoelectron spectroscopy (UPS) measurements were performed on a Thermo Scientific ESCALAB 250Xi photoelectron spectrometer at a base pressure of 2×10⁻⁸ mbar. The UPS used a He—I light (21.2182 eV) as the UV source. X-ray diffraction (XRD) measurements were performed by a Bruker D8 Advance A25 X-ray diffractometer. Scanning electron microscopy (SEM) and energy-dispersive X-ray spectroscopy (EDX) measurements were performed by a Jeol 7500F field emission scanning electron microscope and a Tescan Vega II scanning electron microscope, respectively. Resistivity measurements were performed by a Jandel four-point sheet resistance measurement system. The current-voltage (J-V) characteristic curves were obtained by a Keithley 2401 source meter under AM 1.5G illumination (100 mW/cm²) provided by a Newport Oriel Sol3A solar simulator. The J-V curves were measured with voltage scan from −0.2 V to 1.2 V at a scanning rate of 50 mV/s. Incident photon to current conversion efficiency (IPCE) measurements were performed by a QEXL solar cell quantum efficiency measurement system.

### EXAMPLES

Example 1. A device comprising: a first electrode layer comprising a material having a melting point less than or equal to 200° C.; a first charge transport layer (CTL); and an active layer, wherein: the CTL is positioned between the first electrode layer and the active layer.

Example 2. The device of Example 1, wherein the first electrode layer is characterized by a work function that is aligned with the Fermi level of the CTL.

Example 3. The device of either claim 1 or claim 2, wherein the difference of the Fermi level of the material used to construct the CTL minus the work function of the material used to construct the first electrode layer is between 0.05 eV and 0.6 eV or between 0.1 eV and 0.3 eV Example 4. The device of any one of Examples 1-3, wherein the melting point is less than 150° C.

Example 5. The device of any one of Examples 1-4, wherein the melting point is between 100° C. and 200° C.

Example 6. The device of any one of Examples 1-5, wherein the material comprises a metal.

Example 7. The device of any one of Examples 1-6, wherein the metal comprises at least one of bismuth, lead, tin, cadmium, zinc, indium, gallium, antimony, or thallium.

Example 8. The device of any one of Examples 1-7, wherein the metal comprises bismuth and indium.

Example 9. The device of any one of Examples 1-8, wherein bismuth is present in the first electrode layer at a concentration between 5 wt % and 95 wt %.

Example 10. The device of any one of Examples 1-9, wherein the concentration is between 40 wt % and 60 wt %.

Example 11. The device of any one of Examples 1-10, wherein the first electrode layer has a thickness between 0.1 μm and 50 μm.

Example 12. The device of any one of Examples 1-11, wherein the thickness is between 1 μm and 10 μm.

Example 13. The device of any one of Examples 1-12, wherein the CTL comprises an electron transfer material (ETM).

Example 14. The device of any one of Examples 1-13, wherein the ETM comprises a carbon-containing material.

Example 15. The device of any one of Examples 1-14, wherein the carbon-containing material comprises at least one of a fullerene, a fullerene-based material, or a fullerene-derivative.

Example 16. The device of any one of Examples 1-15, wherein the carbon-containing material comprises at least one of C₆₀, C₇₀, phenyl-C₆₁-butyric acid methyl ester (PCBM), fulleropyrrolidinium iodide [C₆₀-bis], indene-C₆₀ bis-adduct [ICBA], or C₆₀-fused N-methylpyrrolidine-m-C₁₂-phenyl [CMC]).

Example 17. The device of any one of Examples 1-16, further comprising a second electrode layer, wherein the second electrode layer is positioned between the first electrode layer and the CTL.

Example 18. The device of any one of Examples 1-17, wherein the second electrode layer is characterized by a work function that is aligned with the Fermi level of the CTL.

Example 19. The device of claim 1-18, wherein the difference of the work function of the material used to construct at least one of the first electrode layer or the second electrode layer minus the Fermi level of the material used to construct the CTL is between 0.05 eV and 0.6 eV or between 0.1 eV and 0.3 eV Example 20. The device of any one of Examples 1-19, wherein the second electrode layer comprises carbon.

Example 21. The device of any one of Examples 1-20, wherein the second electrode layer comprises at least one of graphite, carbon-black, or a carbon nanotube.

Example 22. The device of any one of Examples 1-21, wherein the carbon nanotube comprises at least one of a single walled carbon nanotube, a double walled carbon nanotube, or a multi-walled carbon nanotube.

Example 23. The device of any one of Examples 1-22, wherein the second electrode layer comprises graphite.

Example 24. The device of any one of Examples 1-23, wherein the second electrode layer further comprises a metal.

Example 25. The device of any one of Examples 1-24, wherein the metal of the second electrode layer comprises a transition metal.

Example 26. The device of any one of Examples 1-25, wherein the metal of the second electrode layer comprises at least one of nickel, cobalt, or tungsten.

Example 27. The device of any one of Examples 1-26, wherein the metal of the second electrode layer is present at a concentration between greater than 0 wt % and less than or equal to 30 wt %.

Example 28. The device of any one of Examples 1-27, wherein the concentration is between 5 wt % and 20 wt %.

Example 29. The device of any one of Examples 1-28, wherein the metal of the second electrode layer is in a particulate form having an average particle size between 10 nm and 10 μm.

Example 30. The device of any one of Examples 1-29, wherein the average particle size is between 500 nm and 2 μm.

Example 31. The device of any one of Examples 1-30, wherein the second electrode layer has a thickness between 0.1 μm and 50 μm.

Example 32. The device of any one of Examples 1-31, wherein the thickness of the second electrode layer is between 0.2 μm and 20 μm.

Example 33. The device of any one of Examples 1-32, wherein the CTL comprises a hole transfer material (HTM).

Example 34. The device of any one of Examples 1-33, wherein the HTM comprises at least one of spiro-OMeTAD, poly(triaryl amine) (PTAA), nickel oxide, or a carbon-containing material.

Example 35. The device of any one of Examples 1-34, wherein the carbon-containing material comprises at least one of graphite, graphene, a fullerene, an amorphous carbon, or a carbon filler.

Example 36. The device of any one of Examples 1-35, wherein the absorber layer comprises a perovskite.

Example 37. The device of any one of Examples 1-36, wherein the perovskite comprises a first cation (A), a second cation (B), and an anion (X).

Example 38. The device of any one of Examples 1-37, wherein A comprises at least one of cesium, an alkyl ammonium, or an amidinium.

Example 39. The device of any one of Examples 1-38, wherein alkyl ammonium comprises at least one of methylammonium, ethylammonium, propylammonium, butylammonium, or dimethylammonium.

Example 40. The device of any one of Examples 1-39, wherein the amidinium comprises at least one formamidinium or guanidinium.

Example 41. The device of any one of Examples 1-40, wherein B comprises at least one of tin or lead.

Example 42. The device of any one of Examples 1-41, wherein X comprises a halogen.

Example 43. A method comprising: synthesizing metal particles; synthesizing a mixture comprising the metal particles and a carbon-containing material; applying the mixture to a device stack comprising a perovskite layer, resulting in the forming of a layer comprising the carbon-containing material and the metal particles; and applying a fusible alloy in liquid form to a surface of the layer comprising the carbon-containing material and the metal particles, resulting in the forming of a solid layer of the fusible alloy.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A device comprising:
a first electrode layer comprising a material having a melting point less than or equal to 200° C.;
a first charge transport layer (CTL); and
an active layer, wherein:
the CTL is positioned between the first electrode layer and the active layer.

2. The device of claim 1, wherein the melting point is between 100° C. and 200° C.

3. The device of claim 1, wherein the material comprises a metal.

4. The device of claim 1, wherein the metal comprises at least one of bismuth, lead, tin, cadmium, zinc, indium, gallium, antimony, or thallium.

5. The device of claim 1, wherein the metal comprises bismuth and indium.

6. The device of claim 5, wherein bismuth is present in the first electrode layer at a concentration between 5 wt % and 95 wt %.

7. The device of claim 1, wherein the first electrode layer has a thickness between 0.1 μm and 50 μm.

8. The device of claim 1, further comprising a second electrode layer, wherein the second electrode layer is positioned between the first electrode layer and the CTL.

9. The device of claim 8, wherein the second electrode layer comprises carbon.

10. The device of claim 8, wherein the second electrode layer comprises at least one of graphite, carbon-black, or a carbon nanotube.

11. The device of claim 8, wherein the second electrode layer comprises graphite.

12. The device of claim 11, wherein the second electrode layer further comprises a metal.

13. The device of claim 12, wherein the metal of the second electrode layer comprises a transition metal.

14. The device of claim 12, wherein the metal of the second electrode layer comprises at least one of nickel, cobalt, or tungsten.

15. The device of claim 12, wherein the metal of the second electrode layer is present at a concentration between greater than 0 wt % and less than or equal to 30 wt %.

17. The device of claim 12, wherein the metal of the second electrode layer is in a particulate form having an average particle size between 10 nm and 10 μm.

17. The device of claim 8, wherein the second electrode layer has a thickness between 0.1 μm and 50 μm.

18. The device of claim 1, wherein the absorber layer comprises a perovskite.

19. The device of claim 18, wherein the perovskite comprises a first cation (A), a second cation (B), and an anion (X).

20. A method comprising:
synthesizing metal particles;
synthesizing a mixture comprising the metal particles and a carbon-containing material;
applying the mixture to a device stack comprising a perovskite layer, resulting in the forming of a layer comprising the carbon-containing material and the metal particles; and
applying a metal or alloy in liquid form to a surface of the layer comprising the carbon-containing material and the metal particles, resulting in the forming of a solid layer of the metal or alloy.
